(19) United States
(12) Patent Application Publication
(10) Pub. No.: US 2006/0011136 A1
(43) Pub. Date: Jan. 19, 2006

(54) Manufacturing apparatus

(75) Inventors: Shunpei Yamazaki, Tokyo (JP); Satoshi Seo, Kanagawa (JP)

Correspondence Address: COOK, ALEX, McFARRON, MANZO,;CUMMINGS & MEHLER, LTD., SUITE 2850, 200 WEST ADAMS STREET, CHICAGO, IL, 60606, US

(73) Assignee: Semiconductor Energy Laboratory Co., Ltd.

(21) Appl. No.: 11/178,855

(22) Filed: Jul. 11, 2005

(30) Foreign Application Priority Data
Jul. 15, 2004 (JP) 2004-208955

(51) Int. Cl. C23C 16/00

(52) U.S. Cl. 118/719

(57) ABSTRACT

It is an object of the present invention to provide a manufacturing apparatus that reduces a manufacturing cost by enhancing efficiency in the use of an EL material and that is provided with a vapor deposition apparatus which is one of manufacturing apparatuses superior in uniformity in forming an EL layer and in throughput in the case of manufacturing a full-color flat panel display using emission colors of red, green, and blue. According to one feature of the invention, a mask having a small opening with respect to a desired vapor deposition region is used, and the mask is moved accurately. Accordingly, a desired vapor deposition region is vapor deposited entirely. In addition, a vapor deposition method is not limited to movement of a mask, and it is preferable that a mask and a substrate move relatively, for example, the substrate may be moved at a μm level with the mask fixed.

### BACKGROUND OF THE INVENTION

1. Field of the Invention

The present invention relates to a film forming apparatus employed for forming a film of a material capable of forming a film by vapor-deposition (hereinafter referred to as a vapor-deposition material) and a manufacturing apparatus provided with the film forming apparatus. In particular, the invention relates to a vapor-deposition apparatus employed for forming a film by evaporating a vapor-deposition material from a vapor-deposition source provided near a substrate. In addition, the invention relates to a light-emitting device and a manufacturing method thereof.

2. Description of the Related Art

A Light-emitting element using an organic compound featuring small thickness and weight, fast response, DC low-voltage drive, and the like as a light-emitting substance has been expected to find application in flat panel displays of the next generation. In particular, a display device in which light-emitting elements are disposed in a matrix has been considered superior to the conventional liquid-crystal display device in that the display device has a wide viewing angle and excellent visibility.

As for the light emission mechanism of the light-emitting elements, voltage is applied to a pair of electrodes by sandwiching a layer containing the organic compound therebetween. Accordingly, it is thought that electrons injected from a cathode and holes injected from an anode are recombined at the light-emitting center in the organic compound layer to form a molecular exciton and that energy is discharged to emit luminescence when the molecular exciton returns to a ground state. A singlet excitation state and a triplet excitation state are known as excited states, and it is considered that luminescence can be obtained by undergoing either excited state.

In a light-emitting device formed by arranging such light-emitting elements in a matrix, driving methods such as a passive matrix driving (simple matrix type) and an active matrix driving (active matrix type) can be employed. However, when the pixels are increased, the active matrix type in which a switch is provided for each pixel (or 1 dot) is considered to be advantageous because low-voltage driving is possible.

In addition, the layer containing an organic compound has a stacked layer structure typified by “hole transporting layer/emission layer/electron transferring layer”. As for a film forming method of these organic compound materials, methods such as an ink-jet method, a vapor-deposition method, and a spin coating method are known. In addition, an EL material for forming an EL layer is roughly classified into a low molecular weight (monomer-based) material and a high molecular weight (polymer-based) material, and the low molecular weight material is deposited using a vapor-deposition apparatus.

The conventional vapor-deposition apparatus has a substrate disposed in a substrate holder and includes a crucible (or a vapor-deposition boat) having an EL material, that is, a vapor-deposition material, introduced therein, a shutter preventing the sublimated EL material from rising, and a heater for heating the EL material located inside the crucible. The EL material heated with the heater is sublimated and a film is formed over the rotating substrate. In order to perform uniform film formation at this time, the distance between the substrate and the crucible is set to 1 m or more.

However, since the film forming accuracy is not so high, a space between different pixels is designed widely and an insulator referred to as a bank is formed between the pixels, when it is considered that a full-color flat panel display is manufactured using emission colors of red, green, and blue.

### SUMMARY OF THE INVENTION

A full-color flat panel display using emission colors of red, green, and blue is increasingly required to have higher definition, higher aperture ration, and higher reliability. Such requirements are problems in miniaturizing each display pixel pitch to make a light-emitting device highly precise (increasing the number of pixels) and downsized. Simultaneously, it is also required to improve the productivity and lower the cost.

With these views, the applicant of the present application has suggested a vapor-deposition apparatus (Reference 1: Japanese Patent Laid-Open No. 2001-247959 and Reference 2: Japanese Patent Laid-Open No. 2002-60926) as a means for solving the foregoing problemst.

The present invention provides a manufacturing apparatus that reduces a manufacturing cost by enhancing efficiency in the use of an EL material and that is provided with a vapor-deposition apparatus which is one of manufacturing apparatuses superior in uniformity in forming an EL layer and in throughput in the case of manufacturing a full-color flat panel display using emission colors of red, green, and blue.

In addition, the invention provides a vapor-deposition apparatus high in vapor-deposition accuracy capable of miniaturizing each display pixel pitch to make a light-emitting device highly precise (increasing the number of pixels) and downsized.

It is vapor-deposition accuracy that becomes a problem in miniaturizing each display pixel pitch to make a light-emitting device highly precise (increasing the number of pixels) and downsized. At a step before vapor-deposition, when a space between different pixels is designed narrowly and an insulator referred to as a bank is formed narrowly between the pixels in designing a layout of the pixels, high precision and miniaturization of each display pixel pitch can be realized. However, at a vapor-deposition step, vapor-deposition accuracy in the conventional vapor-deposition apparatus is not enough when a width of a bank and a width of neighboring pixels are narrowed to be, for example, 10 μm or less.

Consequently, according to one feature of the invention, a mask having a small opening with respect to a desired vapor-deposition region is used, and the mask is moved accurately. Accordingly, a desired vapor-deposition region is vapor deposited entirely.

Specifically, vapor-deposition is repeated by moving the mask at a μm level more than once or vapor-deposition is performed while moving the mask at a μm level. Accordingly, accuracy of the vapor-deposition is ensured. According to the invention, selective vapor-deposition can be performed even when a width of a bank is 10 μm or less, for example.

Generally, a mask is fixed to a mask frame in a stretched state. In addition, strength of the mask can be maintained by making an opening provided for the mask small. In other words, when tension is applied to the mask by being fixed to the mask frame, the mask can be prevented from cracking from an edge of neighboring openings.

In addition, a mask may be formed by an etching method or an electroforming method. A mask may be formed by combining an etching method based on dry etching or wet etching with an electroforming method performed in an electroforming tank of the same metal as that of the vapor-deposition mask.

In addition, a vapor-deposition method is not limited to movement of the mask, and it is preferable that the mask and a substrate move relatively, for example, the substrate may be moved at a μm level with the mask fixed.

Further, a step of forming an EL element, in other words, a step of forming an EL layer over a first electrode to a step of forming a second electrode are performed. This is preferably performed with an integrated closed system capable of avoiding impurity contamination, specifically with a multi-chamber system manufacturing apparatus provided with a load chamber, a transfer chamber connected to the load chamber, and a film forming chamber connected to the transfer chamber and having the high vapor-deposition accuracy, or an in-line system manufacturing apparatus.

According to one feature of the invention disclosed in this specification, a manufacturing apparatus comprises a load chamber; a transfer chamber connected to the load chamber; and a film forming chamber connected to the transfer chamber, wherein the film forming chamber is connected to a pressure reducing chamber that pressure reducing chambers the film forming chamber, wherein the film forming chamber includes a means for moving a substrate for fixing a substrate, a means for moving a mask in an X direction and a Y direction with respect to one side of a substrate in the film forming chamber, an imaging means for aligning the mask and the substrate, a vapor-deposition source below the substrate and the mask, and a means for moving the vapor-deposition source.

In addition, a mask may be fixed to move a substrate slightly. According to another feature of the invention, a manufacturing apparatus comprises a load chamber; a transfer chamber connected to the load chamber; and a film forming chamber connected to the transfer chamber, wherein the film forming chamber is connected to a pressure reducing chamber that reduces the pressure of the film forming chamber, wherein the film forming chamber includes a means for moving a mask for fixing a mask, a means for moving a substrate in an X direction and a Y direction with respect to the mask in the film forming chamber, an imaging means for aligning the mask and the substrate, a vapor-deposition source below the substrate and the mask, and a means for moving the vapor-deposition source.

Moreover, a means for vaporizing such as a vapor-deposition source may be fixed. According to another feature of the invention, a manufacturing apparatus comprises a load chamber; a transfer chamber connected to the load chamber; and a film forming chamber connected to the transfer chamber, wherein the film forming chamber is connected to a pressure reducing chamber that reduces the pressure of the film forming chamber, wherein the film forming chamber includes a means for moving a substrate for fixing a substrate, a means for moving a mask in an X direction and a Y direction with respect to one side of a substrate in the film forming chamber, an imaging means for aligning the mask and the substrate, and a fixed means for vaporizing.

Further, a means for vaporizing such as a vapor-deposition source may be fixed and a mask may be fixed to move a substrate slightly. According to another feature of the invention, a manufacturing apparatus comprises a load chamber; a transfer chamber connected to the load chamber; and a film forming chamber connected to the transfer chamber, wherein the film forming chamber is connected to a pressure reducing chamber that reduces the pressure of the film forming chamber, wherein the film forming chamber includes a means for moving a mask for fixing a mask, a means for moving a substrate in an X direction and a Y direction with respect to the mask in the film forming chamber, an imaging means for aligning the mask and the substrate, and a fixed means for vaporizing.

In each of the above features, according to another feature of the invention, the mask is moved relatively with respect to the substrate simultaneously with performing film formation to the substrate in the film forming chamber. Alternatively, in each of the above features, according to another feature of the invention, a film is formed by repeating film formation more than once after moving the mask respectively with respect to the substrate in the film forming chamber.

Further, in each of the above features, the substrate is provided with a plurality of electrodes arranged regularly, and an insulator between neighboring electrodes for covering electrode ends, wherein one side of an opening provided for the mask is equal to one side of the electrode and an area of the opening is smaller than that of the electrode.

Note that the light-emitting element has a layer containing an organic compound (hereinafter referred to as an EL layer) that provides luminescence (Electro Luminescence) generated by applying an electric field thereto, an anode, and a cathode. Luminescence in the organic compound includes luminescence (fluorescence) that is obtained in returning from a singlet-excited state to a ground state and luminescence (phosphorescence) that is obtained in returning from a triplet-excited state to a ground state. However, a light-emitting device manufactured according to a film forming apparatus and a film forming method of the invention can be applied to the case using either luminescence.

In addition, in this specification, the first electrode refers to an electrode to be an anode or a cathode of the light-emitting element. A structure of the light-emitting element includes the first electrode, the layer containing an organic compound, and the second electrode, and an electrode formed first over a substrate in the sequential order of the formation is referred to as the first electrode.

The first electrode can be disposed in a manner such as strip arrangement, delta arrangement, mosaic arrangement, or the like.

Note that a light-emitting device in this specification refers to an image display device, a light-emitting device, or a light source (including a lighting system). In addition, the light-emitting device includes all of a module in which a connector, for example, an FPC (Flexible Printed Circuit), a TAB (Tape Automated Bonding) tape, or a TCP (Tape Carrier Package) is attached to a light-emitting device, a module in which a printed wiring board is provided at the end of a TAB tape or a TCP, or a module in which an IC (integrated circuit) is directly mounted on a light-emitting element by a COG (Chip On Glass) method.

Moreover, in the light-emitting device according to the invention, a method for driving a screen display is not limited particularly, and a dot-sequential driving method, a line-sequential driving method, or an area-sequential driving method may be used, for example. The line-sequential driving method is typically employed, in which a time division gradation driving method or an area gradation driving method may be employed appropriately. In addition, a video signal to be inputted into a source line of the light-emitting device may be an analog signal or a digital signal, and a driver circuit and the like may be designed appropriately according to the video signal.

Further, light-emitting devices using digital video signals are classified into one in which video signals are inputted into a pixel at a constant voltage (CV), and the other one in which video signals are inputted into a pixel at a constant current (CC). The light-emitting devices in which video signals are inputted into a pixel at a constant voltage (CV) are further classified into one in which a constant voltage is applied to a light-emitting element (CVCV), and the other one in which a constant current is applied to a light-emitting element (CVCC). The light-emitting devices in which video signals are inputted into a pixel at a constant current (CC) is still classified into one in which a constant voltage is applied to a light-emitting element (CCCV), and the other one in which a constant current is applied to a light-emitting element (CCCC).

Furthermore, a protection circuit (a protection diode or the like) may be provided in the light-emitting device according to the present invention to inhibit electrostatic discharge damage.

In addition, in the case of an active matrix type, although a plurality of TFTs connected to the first electrode is provided, the invention can be applied thereto regardless of a TFT structure, and a top gate TFT, a bottom gate (reverse stagger) TFT, or a forward stagger TFT can be used, for example. Further, the invention is not limited to a TFT with a single gate structure; therefore, a TFT with a multi-gate structure having a plurality of channel forming regions, for example, a double gate TFT may be used.

Moreover, a light-emitting element may be electrically connected to either a p-channel TFT or an n-channel TFT. When a light-emitting element is connected to the p-channel TFT, the light-emitting element is preferably formed as follows. The p-channel TFT is connected to an anode and a hole injecting layer, a hole transporting layer, an emission layer, and an electron transporting layer are sequentially stacked over the anode, and thereafter, a cathode is formed. When a light-emitting element is connected to the n-channel TFT, the light-emitting element is preferably formed as follows. The n-channel TFT is connected to a cathode and an electron transporting layer, an emission layer, a hole transporting layer, and a hole injecting layer are sequentially stacked over the cathode, and thereafter, an anode is formed.

Further, an amorphous semiconductor film, a semiconductor film having a crystalline structure, a compound semiconductor film having an amorphous structure, or the like can be appropriately used as an active layer of the TFT. Furthermore, a semi-amorphous semiconductor film (also referred to as a microcrystalline semiconductor film) can also be used. The semi-amorphous semiconductor film has an intermediate structure between an amorphous structure and a crystal structure (also including a single crystal structure and a polycrystal structure), and a third condition that is stable in term of free energy, and further includes a crystalline region having a short-range order along with lattice distortion.

According to the invention, if a full-color flat panel display using emission colors of red, green, and blue is manufactured, much higher definition and higher aperture ration can be realized.

These and other objects, features and advantages of the present invention will become more apparent upon reading of the following detailed description along with the accompanied drawings.

### BRIEF DESCRIPTION OF THE DRAWINGS

In the accompanying drawings:

FIG. 1 is a cross-sectional view showing a vapor-deposition apparatus according to a certain aspect of the present invention (Embodiment Mode 1);

FIG. 2 is a cross-sectional view showing a vapor-deposition apparatus according to a certain aspect of the present invention (Embodiment Mode 1);

FIGS. 3A to 3D are top views each showing that vapor-deposition is to be performed (Embodiment Mode 1);

FIGS. 4A and 4B are top views each showing a vapor-deposition mask and a pixel pattern (Embodiment Mode 1);

FIGS. 5A and 5B are top views each showing a vapor-deposition mask and a pixel pattern (Embodiment Mode 1);

FIGS. 6A and 6B are views each showing an example of a top view of a vapor-deposition apparatus (Embodiment Mode 1);

FIG. 7 is a top view of a multi-chamber system manufacturing apparatus;

FIG. 8 is a top view showing a layout of a pixel;

FIG. 9 is a top view showing a relation between an opening of a mask and a layout of a pixel;

FIG. 10 is a cross-sectional view showing a structure of an active matrix EL display device;

FIGS. 11A and 11B are cross-sectional views each showing a light-emitting element;

FIGS. 12A and 12B are top views of alight-emitting module;

FIGS. 13A and 13B are views each showing an example of an electronic device;

FIGS. 14A to 14E are views each showing an example of an electronic device; and

FIGS. 15A to 15C are a cross-sectional view and nozzle top views each showing a film forming apparatus according to a certain aspect of the present invention (Embodiment Mode 2).

### DETAILED DESCRIPTION OF THE INVENTION

### Embodiment Mode 1

Hereinafter, an embodiment mode according to the present invention is described.

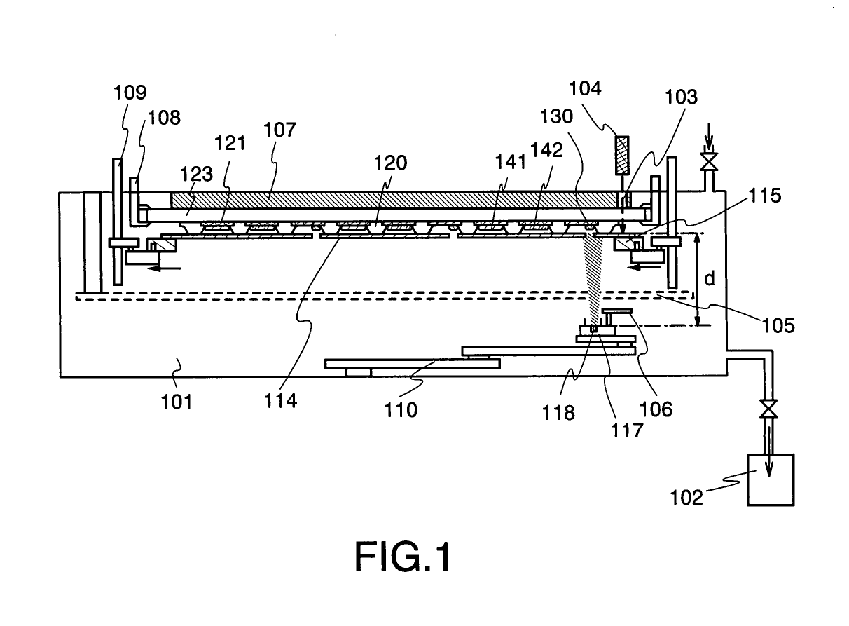

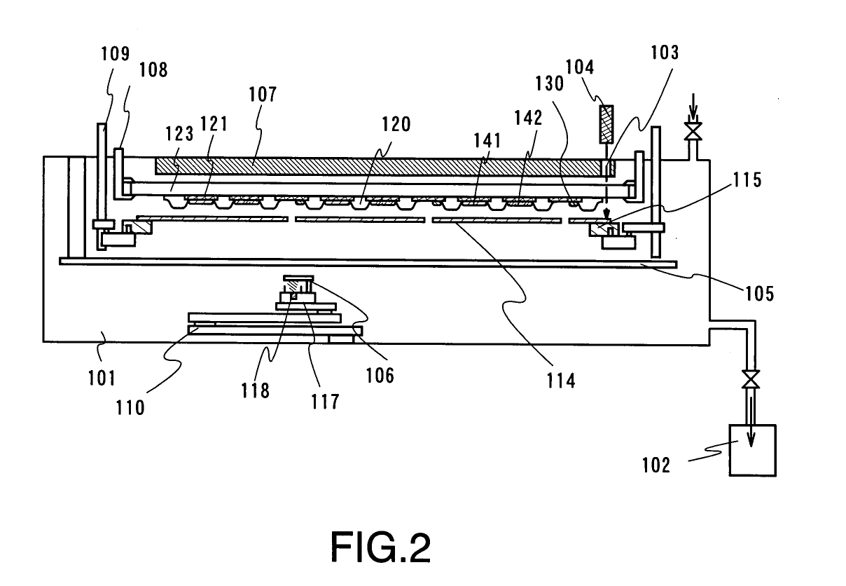

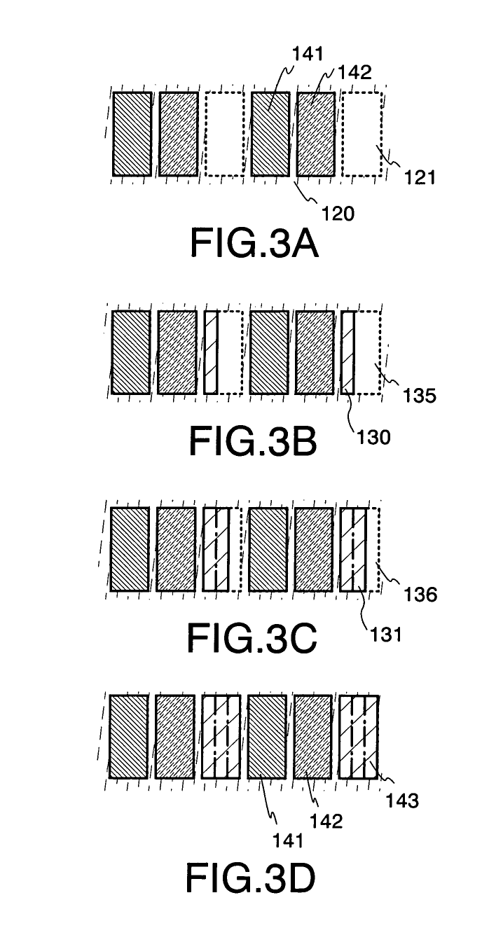

Here, an example of a vapor-deposition apparatus provided in a film forming chamber with a means for moving a mask and a movement unit for moving a vapor-deposition source holder in an X direction or a Y direction is described with reference to FIG. 1, FIG. 2, FIGS. 3A to 3D, FIGS. 4A and 4B, FIGS. 5A and 5B, and FIGS. 6A and 6B. Note that FIG. 1 shows a cross-sectional view of the vapor-deposition apparatus at the time of vapor-deposition.

A film forming chamber 101 is provided with a means for reducing the pressure 102 and a means for introducing an inert gas. A magnetic levitation type turbo-molecular pump, a cryo pump, or a dry pump is used as the means for reducing the pressure 102. According to the means for reducing the pressure 102, it is possible to set a reached pressure of a transfer chamber to be 10⁻⁵ Torr to 10⁻⁶ Torr. In order to prevent impurities from being introduced into the interior of the apparatus, an inert gas such as a rare gas or nitrogen is used for a gas to be introduced. Gases highly purified by a gas purifier before the introduction into the interior of the apparatus is used for these gases introduced into the apparatus. Therefore, it is necessary to prepare a gas purifier to introduce to the film forming apparatus after the gas is highly purified. Accordingly, oxygen, water, or other impurities contained in the gas can be previously removed; therefore, the impurities can be prevented from being introduced into the interior of the apparatus.

In addition, the film forming chamber 101 is provided with a substrate stage 107. A vapor-deposition mask 114 made of a magnetic substance is fixed to the substrate stage 107 by magnetic force, and the substrate stage 107 is installed with an electromagnet and a permanent magnet to fix a substrate 123 disposed therebetween. Further, a transparent window portion 103 is provided, and the position of the substrate 123 and the vapor-deposition mask 114 can be identified by an imaging means 104. The vapor-deposition apparatus shown in FIG. 1 controls a means for moving a substrate 108, a means for moving a mask 109, and a movement unit 110 based on information obtained by the imaging means 104.

The vapor-deposition mask 114 is fixed to a mask frame 115 in a stretched state. In addition, a space distance, d, between the substrate 123 and a vapor-deposition source holder 117 is typically shortened to be 30 cm or less, preferably 5 cm to 15 cm; therefore, there is a chance that the vapor-deposition mask 114 is also heated. Accordingly, it is desirable to use a metal material (for example, a material including a refractory metal such as tungsten, tantalum, chromium, nickel, or molybdenum, or alloys containing such elements, that is, stainless steel, Inconel, or Hastelloy) that has a low thermal expansion coefficient with high resistance to heat-induced deformation for the vapor-deposition mask 114. In particular, it is preferable to use the vapor-deposition mask 114 using a material having the same thermal expansion coefficient as that of the substrate. For example, in the case of using a glass substrate, 42 alloy (Fe—Ni alloy: Ni 42%) or 36 invar (Fe—Ni alloy: Ni 36%) whose thermal expansion coefficient is close to that of glass may be used for the vapor-deposition mask. Although the mask is heated at the time of vapor-deposition, displacement is unlikely to occur because the mask body and the substrate have the same expansion quantity.

Further, an opening width of the vapor-deposition mask 114 is designed smaller than a width of an exposure region of a first electrode 121 not covered with insulator 120. The vapor-deposition mask maintains its strength by reducing the size of the opening.

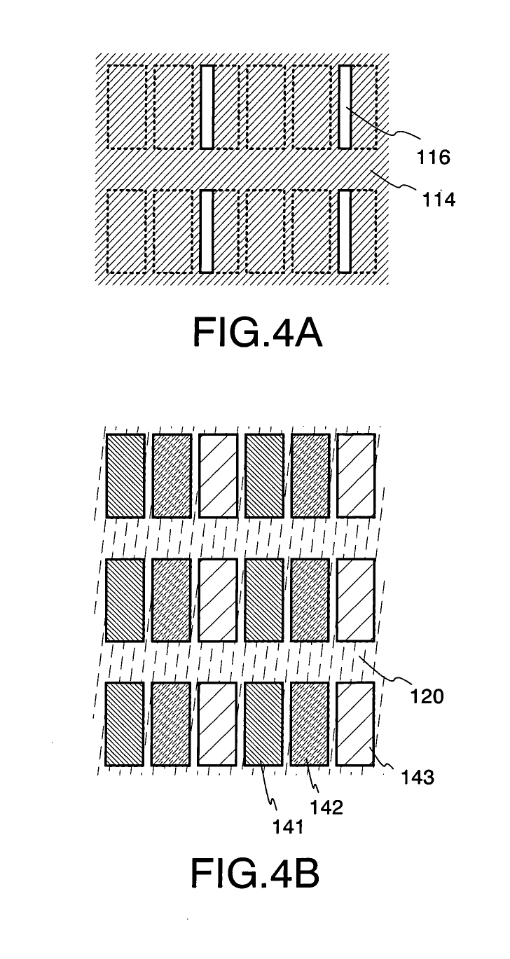

Even when an opening size of the vapor-deposition mask 114 is small, vapor-deposition can be performed to a region broader than the opening size and to an exposed region of the first electrode 121 that is not covered with insulator 120 by moving the vapor-deposition mask. Note that FIG. 4A shows an example of an opening pattern of a vapor-deposition mask 114, and a width of one opening 116 corresponds to one thirds of an exposure region of the first electrode shown by a dotted line. Finally, a vapor-deposited film (R) 141, a vapor-deposited film (G) 142, and a vapor-deposited film (B) 143 can be obtained precisely in a substrate state shown in FIG. 4B, in other words, in a region surrounded with the insulator 120 by using the vapor-deposition mask 114 shown in FIG. 4A.

The means for moving a mask 109 is provided with a projection that is just fitted into a depression provided for the mask frame 115, of which mechanism is to move the mask frame 115 and the vapor-deposition mask 114 when the means for moving a mask 109 is moved.

The means for moving a substrate 108 is provided to hold or move the substrate 123. When it is desired to move only the vapor-deposition mask 114 by the means for moving a mask 109, the position of the substrate 123 is held by the means for moving a substrate 108. When not only the vapor-deposition mask 114 but also the substrate 123 has moved by the means for moving a mask 109, only the substrate 123 can be moved to a desired position by the means for moving a substrate 108. In addition, the vapor-deposition mask 114 is kept in close contact with the substrate if the means for moving a substrate 108 is not provided, when it is desired to make apart the distance between the vapor-deposition mask 114 fixed by magnetic force and the substrate stage 123.

When only the vapor-deposition mask 114 is moved with the vapor-deposition mask 114 kept in close contact with the substrate 123, a surface of the vapor-deposition mask 114 being in contact with the substrate 123 may be provided with a DLC (Diamond Like Carbon) film so that the substrate 123 is not damaged due to friction. In addition, a surface of the insulator 120 being in contact with the vapor-deposition mask 114 may be provided with a DLC film so that the substrate 123 is not damaged due to friction.

According to the invention, the substrate and the mask are moved in parallel without being rotated at the time of vapor-deposition. Vapor-deposition is performed to the substrate 123 by moving the vapor-deposition source holder 117 in an X direction, a Y direction, or a Z direction by the movement unit 110 at the time of vapor-deposition.

Hereinafter, an example showing a procedure of vapor-deposition by using the vapor-deposition apparatus of FIG. 1 is shown. Note that FIGS. 3A to 3D are each a top view of an appearance showing that vapor-deposition is performed to an exposure region of a first electrode 121. In FIGS. 3A to 3D, the same parts as FIG. 1 are denoted by the same reference numerals.

First, reducing pressure is performed in the film forming chamber 101 by the means for reducing the pressure 102 so that the pressure is 5×10⁻³ Torr (0.665 Pa) or less, preferably 10⁻⁴ Torr to 10⁻⁶ Torr.

Secondly, the vapor-deposition mask 114 and the mask frame 115 are introduced into the film forming chamber 101. The thickness of the vapor-deposition mask 114 is 10 μm to 100 μm and fixed to the mask frame 115 in a stretched state. The mask frame 115 has a depression, which is moved below the substrate stage 107 by the means for moving a mask 109 to perform aligning.

The substrate 123 provided with the first electrode 121 arranged regularly and the insulator 120 covering an end thereof is carried in the film forming chamber 101 with facedown. Then, the substrate 123 is moved below the substrate stage 107 by the means for moving a substrate 108 to perform aligning. Note that FIG. 1 shows an example in which a vapor-deposited film (R) 141 and a vapor-deposited film (G) 142 are vapor deposited to the substrate 123 in advance as shown in FIG. 3A in another film forming chamber. It is preferable to perform vapor-deposition in a separated film forming chamber in consideration of preventing different vapor-deposition materials from being mixed and improving throughput in manufacturing a full-color flat panel display using emission colors of red (R), green (G), and blue (B).

While identifying a position of the substrate 123 and the vapor-deposition mask 114 by imaging means 104, the vapor-deposition mask 114 is brought close to the substrate stage 107 to fix the substrate 123 and the vapor-deposition mask 114 by the magnetic force of the substrate stage 107. A first aligning of the substrate 123 and the vapor-deposition mask 114 is performed at this step. Note that it is preferable to provide a marker that can be identified by the imaging means 104 for the substrate 123 and the vapor-deposition mask 114.

Next, the vapor-deposition source holder 117 is moved below the substrate 123 by the movement unit 110 to start first vapor-deposition. At the vapor-deposition, a vapor-deposition material 118 is evaporated (vaporized) in advance due to resistant heat, and the vapor-deposition material 118 is scattered toward the substrate 123 by opening a vapor-deposition source shutter 106 and a shutter 105 at the time of vapor-deposition. Note that the vapor-deposition source holder 117 may be kept placed in an installation chamber (herein, not shown in the figure) adjacent to the film forming chamber 101 until the vapor-deposition rate becomes stable. The installation chamber is also kept in the same pressure degree as that of the film forming chamber 101 by the means for reducing the pressure. The advantage of providing the installation chamber is that contamination of the film forming chamber 101 can be prevented by avoiding setting the vapor-deposition material to the vapor-deposition source holder 117 and keeping the vapor-deposition source holder 117 placed until the vapor-deposition rate becomes stable in the film forming chamber 101.

The evaporated material is scattered above and selectively vapor deposited to the substrate 123 through an opening provided for the vapor-deposition mask 114. As shown in FIG. 1, since an opening of the vapor-deposition mask 114 is small, only a part of the first electrode 121 is vapor deposited and thus a vapor-deposited vapor-deposition material (B) 130 is formed. FIG. 3B shows a top view of the substrate at this step. As shown in FIG. 3B, a portion 135 of the exposed first electrode that is not vapor-deposited yet exists at this step.

FIG. 1 is a view showing first vapor-deposition in halfway and thereafter second aligning of the substrate 123 and the vapor-deposition mask 114 is performed. In the case of performing the second aligning, the vapor-deposition source shutter 106 and the shutter 105 are closed, the means for moving a substrate 108 and the means for moving a mask 109 are moved below, the substrate 123 and the vapor-deposition mask 114 are kept away from the substrate stage 107 for some extent, and further the substrate 123 and the vapor-deposition mask 114 are kept away from each other for some extent.

Then, the vapor-deposition mask 114 and the substrate 123 are moved relatively by the means for moving a mask 109 or the means for moving a substrate 108. Here, the means for moving a mask is moved at a μm level and aligning is performed by the imaging means 104 to a portion of the first electrode 121 that is not vapor deposited yet. FIG. 2 shows a cross-sectional view of a vapor-deposition apparatus at this step. In FIG. 2A, the same parts as FIG. 1 are denoted by the same reference numerals.

When the substrate stage 107 is provided with an electromagnet, the electromagnet is turned ON at the time of vapor-deposition, and the vapor-deposition mask 114 can be moved below easily by turning the electromagnet OFF at the time of the second aligning.

Next, the vapor-deposition source holder 117 is moved below the substrate 123 by the movement unit 110 to start second vapor-deposition. FIG. 3C shows a top view of the substrate at this step. As shown in FIG. 3C, since an opening of a vapor-deposition mask is small, only a part of the first electrode 121 is vapor deposited and thus a vapor-deposited vapor-deposition material (B) 131 is formed. As shown in FIG. 3C, a portion 136 of the exposed first electrode that is not vapor deposited yet exists at this step.

The third aligning of the substrate 123 and the vapor-deposition mask 114 is performed in the same manner as the foregoing procedure to start third vapor-deposition. There is no portion of the first electrode 121 that is not vapor deposited yet according to the foregoing procedure and thus a vapor-deposited film (B) 143 can be formed as shown in FIG. 3D.

Then, a second electrode is formed over the vapor-deposited film (R), the vapor-deposited film (G), and the vapor-deposited film (B) with another film forming chamber to complete a light-emitting element. Here, although a single layer of the vapor-deposited film is shown for simplification, in fact, the light-emitting element is formed of a plurality of stacked layers such as a hole injecting layer, a hole transporting layer, an emission layer, an electron transporting layer, or an electron injecting layer. Among these layers, the vapor-deposited film in which vapor-deposition has to be performed selectively per pixel depending on an emission color may be formed with the film forming apparatus shown in FIG. 1. In addition, among these layers, the layers common to RGB pixels are preferably formed employing a coating method or the conventional vapor-deposition apparatus.

Here, an example in which a width of one opening 116 corresponds to one thirds of an exposure region of the first electrode 121 and one vapor-deposited film (B) is formed by performing the first aligning, the first vapor-deposition, the second aligning, the second vapor-deposition, third aligning, and the third vapor-deposition is shown. However, a plurality of vapor-deposition and aligning may be further repeated without particularly limiting thereto.

In addition, as mentioned above, vapor-deposition may be performed while performing aligning by moving the vapor-deposition mask 114 continuously, without performing aligning and vapor-deposition sequentially more than once. Specifically, the vapor-deposited film (B) 143 is formed by performing vapor-deposition continuously while performing aligning by slightly moving the means for moving a mask 109 in the direction shown by an arrow in FIG. 1 only with the substrate 123 fixed by the means for moving a substrate 108. In this case, since the means for moving a mask 109 is moved with the vapor-deposition mask 114 kept in close contact with the insulator 120, the insulator 120 is preferably hard, and a face of the vapor-deposition mask 114 on the substrate 123 side preferably has high planarity.

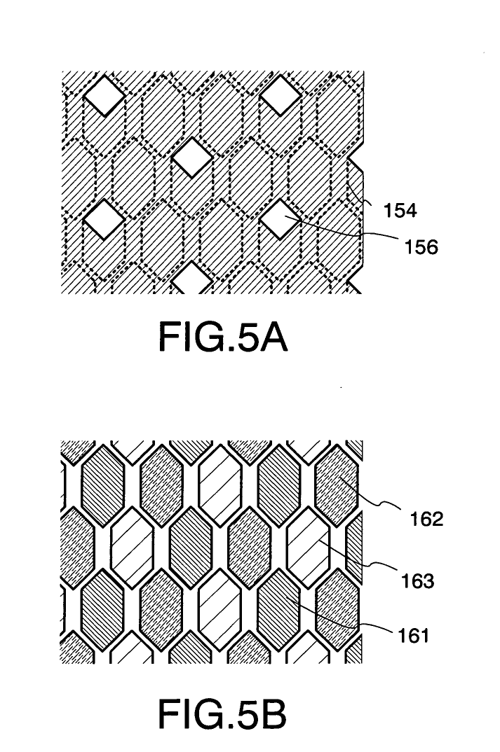

Moreover, a pixel array is not limited particularly, and as exemplified in FIG. 5B, a shape of one pixel may be a polygon, for example, a hexagon to realize a full color display by disposing a vapor-deposited film (R) 161, a vapor-deposited film (G) 162, and a vapor-deposited film (B) 163. In order to form a polygonal pixel shown in FIG. 5B, a vapor-deposition mask 154 having a rhombic opening 156 shown in FIG. 5A may be used to perform vapor-deposition to form the pixel while moving the vapor-deposition mask 154 continuously.

Further, in the vapor-deposition apparatus shown in FIG. 1, the vapor-deposition source holder 117 includes a crucible, a heater set outside of the crucible through a soaking member, a heat insulating layer set outside of the heater, an outer casing which stores these members therein, a cooling pipe rounded around the outside of the outer casing, and the vapor-deposition source shutter 106 that opens and closes an opening of the outer casing including the opening of the crucible. In this specification, the crucible is a cylindrical container having a relatively large opening formed of a material such as sintered boron nitride (BN), a sintered compact of boron nitride (BN) and aluminum nitride (AlN), quartz, or graphite so as to be capable of withstanding a high temperature, a high pressure, and a low pressure.

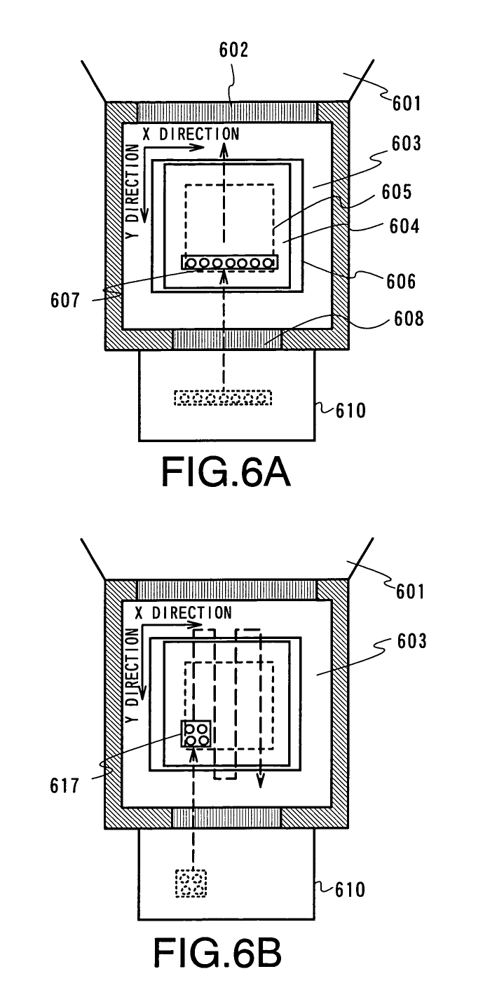

The top face shape of a vapor-deposition source holder 607 is preferably wider than a pixel region 605 to be a long and thin shape as shown in FIG. 6A. FIG. 6A is an example in which a film forming chamber 603 is provided as one chamber of a manufacturing apparatus, and the film forming chamber 603 is connected to an installation chamber 610 and a transfer chamber 601. Seven crucibles are disposed in parallel in the vapor-deposition source holder 607, which enables vapor-deposition in the long and thin region. A shutter 608 is opened and the vapor-deposition source holder 607 kept placed in the installation chamber 610 moves (or shuttles) in the direction shown by the dotted-line arrow below a pixel region 605 provided for a substrate 604; therefore, vapor-deposition is performed. In addition, a vapor-deposition mask 606 can be moved in an X direction or a Y direction and the vapor-deposition source holder 607 can be moved more than once, too. The vapor-deposition mask 606 may be moved to perform vapor-deposition in the same manner as the foregoing method. When a shutter for transferring a substrate 602 is opened, the substrate after the vapor-deposition is transferred to the transfer chamber 601.

FIG. 6B shows another example. FIG. 6B is the same as FIG. 6A except that a shape of a vapor-deposition source holder and a movement path; therefore, detailed description is omitted. In FIG. 6B, there is a square vapor-deposition source holder 617, where four crucibles are disposed. Vapor-deposition is performed by moving the vapor-deposition source holder 617 in zigzag below a substrate 604. A vapor-deposition mask 606 may be moved to perform vapor-deposition in the same manner as the foregoing method.

A film forming rate is preferably designed to be controlled by a microcomputer.

It is preferable that the film forming chamber or the vapor-deposition source holder is provided with a film thickness monitor. When the film thickness of the vapor-deposited film is measured using the film thickness monitor, for example, a quartz oscillator, a change in mass of a film vapor-deposited to the quartz oscillator can be measured as a change in the resonance frequency.

In the vapor-deposition apparatus shown in FIG. 1, at the time of vapor-deposition, a space distance, d, between the substrate 123 and the vapor-deposition source holder 117 is typically shortened to be 30 cm or less, preferably 20 cm or less, more preferably 5 cm to 15 cm. Therefore, efficiency in the use of the vapor-deposition material and throughput are improved significantly.

Although FIG. 1 exemplified an example of performing vapor-deposition by moving the vapor-deposition source holder 117, the vapor-deposition may be performed by moving the substrate 123 and the vapor-deposition mask 114 by the means for moving a substrate 108 and the means for moving a mask 109, with the vapor-deposition source holder 117 fixed to vicinity of the center of the vapor-deposition apparatus during the vapor-deposition. In this case, before the vapor-deposition, the vapor-deposition source holder 117 is moved only from the installation chamber to the vicinity of the center of the vapor-deposition apparatus.

### Embodiment Mode 2

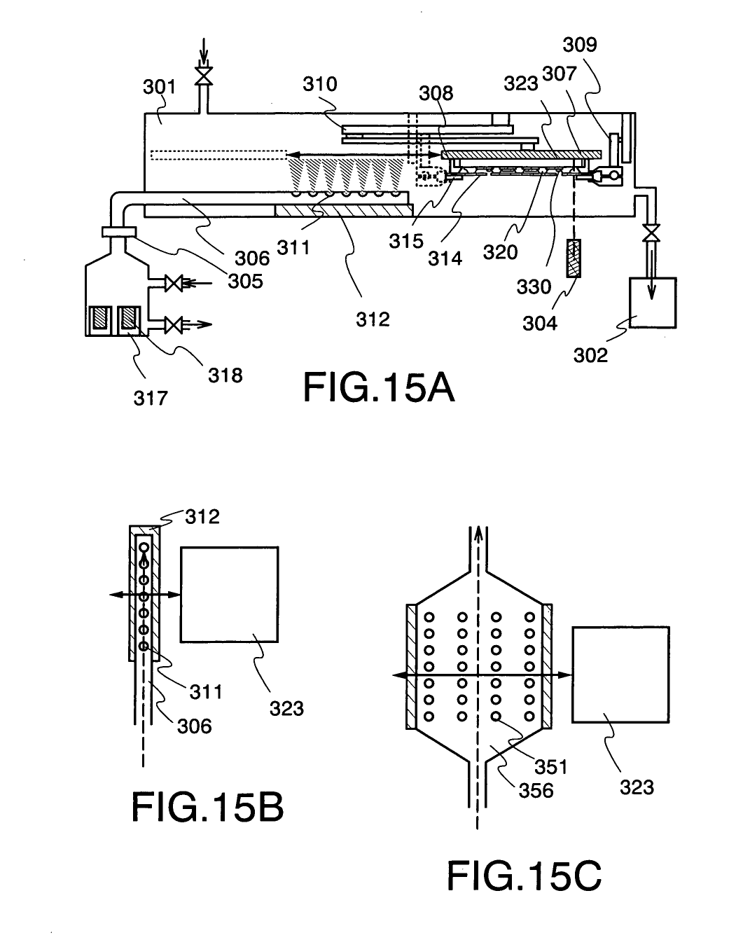

Hereinafter, a film forming apparatus different from that in Embodiment Mode 1 is described. FIG. 15A shows a cross-sectional view of the film forming apparatus.

A film forming chamber 301 is provided with a means for reducing the pressure 302, a movement unit 310 of a substrate, a means for moving a mask 309, an imaging means 304, and a nozzle 306.

The nozzle 306 is provided with seven openings 311 and FIG. 15B shows an example of a top view of the nozzle. As shown in FIG. 15B, a film is formed by moving or shuttling a substrate 323 in the direction of the arrow.

In addition, the nozzle 306 is connected to a treatment chamber for vaporizing a film forming material 318 by interposing a flow control device 305 such as a mass flow controller or a bulb. This treatment chamber is also provided with a means for reducing the pressure, which is designed to be able to adjust pressure within the treatment chamber. The film forming material 318 is placed in a container holder 317 and heating is performed to vaporize the film forming material 318 by a vaporize means (such as resistant heating, electron beam heating, high-frequency induction heating, or laser beam heating) mounted on the container holder 317. This treatment chamber and the film forming chamber 301 are kept in the same pressure degree and the film forming material 318 vaporized from an opening 311 via the nozzle 306 is discharged. It is preferable to provide a heating means 312 in contact with the nozzle 306 to prevent the film forming material 318 from clogging the opening 311 and adhering to an interior wall of the nozzle. Further, it is also preferable to provide an interior wall of the treatment chamber with a heating means so that the film forming material does not adhere.

The film forming material 318 is not limited particularly as long as it is a substance with which a film can be formed by a phase-deposition method (for example, a vapor-phase deposition method, a metal organic chemical vapor-deposition (MOCVD) method, or a molecular beam epitaxy (MBE) method) and various materials can be used. In addition, the film forming material 318 may be in a particle state, a liquid state, or a gelatinous state.

Further, a film forming material that is vaporized may be introduced into the film forming chamber 301 by using a carrier gas. In this case, the film forming material 318 that is vaporized is discharged using the carrier gas from the opening 311 via the nozzle 306. In addition, this treatment chamber is also provided with a means for introducing a carrier gas such as an inert gas and thus the pressure can be increased than that in the film forming chamber 301. A film can be formed over the substrate 323 while constantly controlling the film forming material 318 that is vaporized as well as the carrier gas with the flow control device 305 by increasing the pressure than that in the film forming chamber 301. In addition, the gas dried or heated in advance is preferably used as the carrier gas for introducing into the treatment chamber.

The shape of the nozzle 356 and the number of openings 351 are not limited particularly and a film can be formed in a planar shape by increasing the number of openings with a certain width of the nozzle as another example shown in FIG. 15C.

In FIGS. 15A to 15C, although the nozzle 306 and 356 has an edge, the nozzle may be in a ring state without particularly limiting thereto. As exemplified in FIG. 15C, a system in which the film forming material that is vaporized is circulated by extending a nozzle 356 and coupling the edge of the nozzle with the treatment chamber where the film forming material is disposed may be employed. In FIG. 15C, the film forming material that is vaporized flows in the direction shown by the arrow in FIG. 15C. In this case, the film forming material that is not discharged from the opening is placed back to the treatment chamber without any change and can be used again, which improve the efficiency of the material. In FIG. 15C, the nozzle 356 is provided with 7×4 pieces of the openings 351. In the case of using the nozzle 356 shown in FIG. 15C, a film is formed by moving or shuttling the substrate 323 in the direction of the arrow.

In addition, the treatment chamber can be provided with a plurality of material container holders 317 and a film can be formed over the substrate by mixing different film forming materials.

Moreover, the substrate 323 is fixed to a substrate stage 307 by a means for holding a substrate 308. The substrate stage 307 can move freely in the film forming chamber 301 by the movement unit 310. In addition, the mask 314 is formed of a magnetic material and fixed to a mask frame 315 formed of a magnetic material in a stretched state. This mask frame 315 can move only in a Z direction by the means for moving a mask 309. Further, the substrate stage 307 is installed with an electromagnet, and when the mask frame 315 is brought close with the electromagnet ON, the substrate 323 and the mask 314 are fixed by interposing the substrate 323. The imaging means 304 is used for the aligning of the mask 314 and the substrate 324, and the aligning is performed by moving the substrate 324 with the movement unit 310, whereas fixing the mask 314 by the means for moving a mask 309.

In a film forming apparatus of the present invention shown in FIG. 15A, a film is formed in a desired region by performing the aligning of the mask and film forming more than once. Since the opening of the mask is small, a film is formed only in a part of the desired region. However, a film can be formed in the entire desired region by shifting the substrate with respect to the mask more than once and performing vapor-deposition more than once.

FIG. 15A shows that a film formed portion (B) 330 is formed after forming a film once to a substrate where a film (R) and a film (G) are formed in advance, which shows a step grasping the mask frame 315 and the mask 314 by the means for moving a mask 309. Thereafter, after turning the electromagnet OFF, the mask frame 315 and the mask 314 are kept away from the substrate 323 by moving in a Z direction and new aligning is performed by the imaging means 304. Note that the means for moving a mask 309 may be made possible to move not only in the Z direction but also in an X direction or a Y direction.

While performing aligning of the mask 314, introduction of the vaporized film forming material can be stopped by the flow control device.

After finishing the aligning of the mask 314, the mask 314 is fixed turning the electromagnet ON to keep the means for moving a mask 309 away from the mask 314 and the mask frame 315. Then, a film is formed moving the substrate stage 307 by the movement unit 310 so that the substrate 323 passes above the opening 311 of the nozzle 306.

Although FIG. 15A shows only two of the means for moving a mask 309 in a solid line and the means for moving a mask in a dotted line for simplification of FIG. 15A, at least four means for moving a mask are necessary in total to perform aligning at the four corners of the substrate.

By using the film forming apparatus each shown in FIGS. 15A, 15B, and 15C, throughput can be improved keeping high film forming accuracy.

This embodiment mode can be arbitrarily combined with Embodiment Mode 1.

The invention having the foregoing structure is described in more detail in the following embodiments.

### Embodiment 1

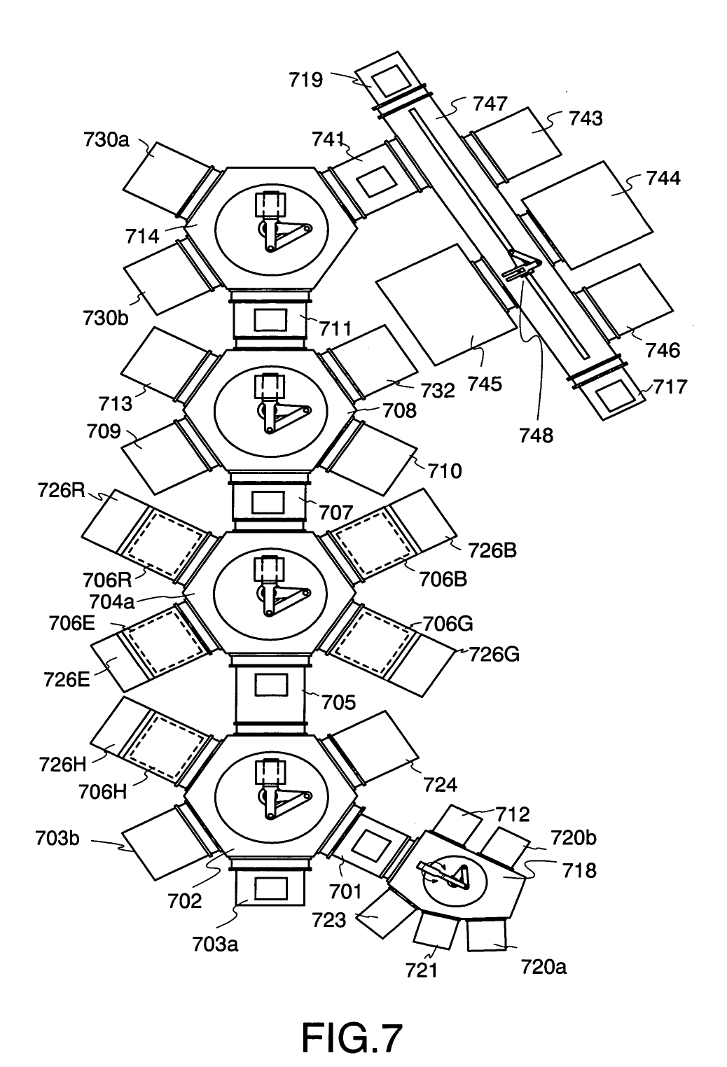

In this embodiment, FIG. 7 shows an example of a multi-chamber system manufacturing apparatus in which a manufacturing process from the formation of an organic compound formed over a first electrode to the formation of a second electrode to perform sealing is automated. Contamination of impurities such as moisture is prevented and throughput is improved by employing one unit.

FIG. 7 is a top view of a manufacturing apparatus having transfer chambers 702, 704a, 708, 714, 718, and 747; delivery chambers 705, 707, 711, and 741; a preparation chamber 701; a first film forming chamber 706H; a second film forming chamber 706B; a third film forming chamber 706G; a fourth film forming chamber 706R; a fifth film forming chamber 706E; other film forming chambers 709, 710, 712, 713, and 732; installation chambers 726R, 726G, 726B, 726E, and 726H for providing a vapor-deposition material in a vapor-deposition source holder; a baking chamber 723; pretreatment chambers 703a and 703b; a mask stock chamber 724; substrate stock chambers 730a and 730b; cassette chambers 720a and 720b; a tray attachment stage 721; a curing chamber 743; an attaching chamber 744; a chamber 745 for forming a sealing material; a pretreatment chamber 746; a sealing substrate loading chamber 717; and an unloading chamber 719. Note that each transfer chamber is provided with a transfer unit. In addition, a gate valve is provided between each treatment chamber for performing reducing pressure.

Hereinafter, a procedure for manufacturing a light-emitting device by carrying a substrate provided with an anode (the first electrode) and an insulator (a bank) for covering ends of the anode in advance in the manufacturing apparatus shown in FIG. 7 is shown. In the case of manufacturing an active matrix light-emitting device, a plurality of thin film transistors (current control TFTs) connecting to the anode and other thin film transistors (such as switching TFTs) as well as a driver circuit formed of a thin film transistor is provided over the substrate in advance. In addition, also in the case of manufacturing a simple matrix light-emitting device, the device can be manufactured with the manufacturing apparatus shown in FIG. 7.

First, the substrate is set at the cassette chamber 720a or 720b. When the substrate is a large-sized substrate (for example, a size of 300 mm×360 mm), the substrate is set in the cassette chamber 720b. When the substrate is an ordinary sized substrate, the substrate is set in the cassette chamber 720a and then transferred to the tray attachment stage 721 to set a plurality of substrates in a tray (for example, a size of 300 mm×360 mm).

The substrate (the substrate provided with an anode and an insulator for covering ends of the anode) set at the cassette chamber 720a and 720b is transferred to the transfer chamber 718. The transfer chamber 718 is provided with a transfer unit (such as a transfer robot) for transferring or reversing a substrate. The transfer robot provided in the transfer chamber 718 can invert the substrate and carry the inverted substrate in the treatment chamber connected to the transfer chamber 718.

Before setting the substrate in the cassette chamber 720a and 720b, it is preferable to remove surface dust by washing the surface of the first electrode (anode) with a porous sponge (typically formed from PVA (polyvinyl alcohol), Nylon, or the like) containing a surfactant (with weak alkaline properties) in order to reduce point defects. A washing apparatus having a roll brush (manufactured from PVA) which rotates around an axial line parallel to the substrate surface and is in contact with the substrate surface may be used or a washing apparatus having a disk brush (manufactured from PVA) which rotates around an axial line perpendicular to the substrate surface and is in contact with the substrate surface may be used as the washing unit. In addition, before forming a film containing an organic compound, it is preferable to perform annealing for degassing under low pressure condition in order to remove moisture or other gases contained in the substrate, and the substrate is preferably transferred to the baking chamber 723 connected to the transfer chamber 718 to perform annealing there.

Secondly, the substrate is transferred from the transfer chamber 718 provided with the substrate transfer unit to the preparation chamber 701. The preparation chamber 701 is connected to a pressure reducing chamber, and can be reduced pressure or can be made in an atmospheric pressure by introducing an inert gas after reducing pressure.

Then, the substrate is transferred to the transfer chamber 702 connected to the preparation chamber 701. It is preferable to reduce pressure of the transfer chamber 702 in advance to keep the transfer chamber 702 in a reduced pressure so that moisture or oxygen does not exist in the transfer chamber 702 as much as possible. Note that the transfer chamber 702 is provided with a transfer unit (such as a transfer robot) for transferring or reversing a substrate and a reducing pressure means, and also other transfer chambers 704a, 708, and 714 are each provided with a transfer unit and a reducing pressure means as well.

In addition, in order to prevent shrinking, it is preferable to perform heating under reduced pressure immediately before vapor-deposition of a film containing an organic compound. Thus, the substrate is transferred to the pretreatment chamber 703b, and annealing for degassing is performed under reduced pressure (5×10⁻³ Torr (0.665 Pa) or less, preferably 10⁻⁴ Torr to 10⁻⁶ Torr) in order to remove moisture or other gases contained in the substrate. In the pretreatment chamber 703b, a plurality of substrates is uniformly heated by using flat-plate heaters (typically, sheath heaters). In particular, when an organic resin film is used as a material for an insulating film or a bank, some of organic resin materials easily adsorb moisture and there is a risk of degassing. Therefore, an effective approach is to perform heating at a temperature of 100° C. to 250° C., preferably at 150° C. to 200° C., for example, for 30 minutes or more and then perform natural cooling for 30 minutes and perform reducing pressure heating to remove the adsorbed moisture before forming a layer containing an organic compound.

After performing the heating under reduced pressure, the substrate is transferred from the transfer chamber 702 to the delivery chamber 705, and further, the substrate is transferred from the delivery chamber 705 to the transfer chamber 704a without being exposed to an atmosphere.

Thereafter, the substrate is appropriately transferred to the film forming chambers 706R, 706G, 706B, and 706E each connected to the transfer chamber 704a, and organic compound layers formed of a low molecular substance which each serves as a hole injecting layer, a hole transporting layer, an emission layer, an electron transporting layer, or an electron injecting layer are appropriately formed. In addition, vapor-deposition can be performed by transferring the substrate from the transfer chamber 702 to the film forming chamber 706H. The installation chambers 726R, 726G, 726B, 726H, and 726E each having a reducing pressure means connected to each of the film forming chambers 706R, 706G, 706B, 706H, and 706 E are in a reduced pressure atomosphere or an inert gas atmosphere, in which various components of the vapor-deposition source holder is exchanged and the vapor-deposition material is supplemented and exchanged; therefore, cleanness of the film forming chamber can be maintained.

A light-emitting element which emits full-color emission (specifically, red, green, and blue) as the entire light-emitting elements can be formed by appropriately selecting the EL materials for installing in the film forming chamber 706H, 706B, 706G, 706R, and 706E. For example, a vapor-deposition mask for R is used in the film forming chamber 706R, and a hole transporting layer or a hole injecting layer, an emission layer (R), and an electron transporting layer or an electron injection layer are sequentially stacked. A vapor-deposition mask for G is used in the film forming chamber 706G, and a hole transporting layer or a hole injecting layer, an emission layer (G), and an electron transporting layer or an electron injecting layer are sequentially stacked. In addition, a vapor-deposition mask for B is used in the film forming chamber 706B, and a hole transporting layer or a hole injecting layer, an emission layer (B), and an electron transporting layer or an electron injecting layer are sequentially stacked. Thereafter, full-color light-emitting elements can be obtained by forming a cathode.

The hole injecting layer can be formed using a material having high hole injectability such as molybdenum oxide (MoOₓ), 4,4′-bis[N-(1-naphthyl)-N-phenyl-amino]-biphenyl (α-NPD), copper phthalocyanine (CuPc), vanadium oxide (VOₓ), ruthenium oxide (RuOₓ), or tungsten oxide (WOₓ).

In addition to α-NPD, the hole transporting layer can be formed using a material having high hole transportability typified by an aromatic amine-based compound such as 4,4′-bis[N-(3-methylphenyl)-N-phenyl-amino]-biphenyl (abbreviated as TPD), 4,4′,4″-tris(N,N-diphenyl-amino)-triphenylamine (abbreviated as TDATA), or 4,4′,4′″-tris[N-(3-methylphenyl)-N-phenyl-amino]-triphenyla mine (abbreviated as MTDATA).

The emission layer emitting red light can be formed using a material such as Alq₃:DCM or Alq₃:rbrene:BisDCJTM.

The emission layer emitting green light can be formed using a material such as Alq₃:DMQD(N,N′-dimethylquinacridon) or Alq₃: coumarin6.

The emission layer emitting blue light can be formed using a material such as α-NPD or tBu-DNA.

In addition to Alq₃ (tris(8-quinolinolato)aluminum), the electron transporting layer can be formed using a material having high electron transportability typified by a metal complex or the like having a quinoline skeleton or a benzoquinoline skeleton such as tris(4-methyl-8-quinolinolato)aluminum (abbreviated as Almq₃), bis(10-hydroxybenzo[h]-quinolinato)beryllium (abbreviated as BeBq₂), or bis(2-methyl-8-quinolinolato)-4-phenylphenolato-aluminum (abbreviated as BAlq). Besides, a metal complex having an oxazole-based and thiazole-based ligand such as bis[2-(2-hydroxyphenyl)-benzooxazolate]zinc (abbreviated as Zn(BOX)₂) or bis[2-(2-hydroxyphenyl)-benzothiazolate]zinc (abbreviated as Zn(BTZ)₂) can be used. Further, besides the metal complex, the following materials can be used as the electron transporting layer owing to high electron transportability: 2-(4-biphenylyl)-5-(4-tert-buthylphenyl)-1,3,4-oxadiazole (abbreviated as PBD), 1,3-bis[5-(p-tert-buthylphenyl)-1,3,4-oxadiazole-2-yl]benzene (abbreviated as OXD-7), 3-(4-tert-buthylphenyl)-4-phenyl-5-(4biphenylyl)-1,2,4-triazole (abbreviated as TAZ), 3-(4-tert-buthylphenyl)-4-(4-ethylpheyl)-5-(4-biphenylyl)-1,2,4-triazole (abbreviated as p-EtTAZ), bathophenanthroline (abbreviated as BPhen), bathocuproin (abbreviated as BCP), or the like.

The electron injecting layer can be formed using a material having high electron injectability such as 4,4-bis (5-methylbenzoxazol-2-yl) stilbene (abbreviated as BzOs) or a compound or the like of an alkaline metal or an alkaline earth metal like CaF₂, lithium fluoride (LiF), cesium fluoride (CsF), or the like. Besides, a material in which Alq₃ and magnesium (Mg) are mixed can also be used.

Among the film forming chambers 706R, 706G, and 706B, at least one chamber is the vapor-deposition apparatus shown in FIG. 1. Vapor-deposition with high accuracy can be performed by performing vapor-deposition while sliding a vapor-deposition mask having an opening shown in FIG. 4A by using the vapor-deposition apparatus shown in FIG. 1. Note that the vapor-deposition mask is stocked in the mask stock chamber 724 and appropriately transferred to the film forming chamber at the time of the vapor-deposition.

In addition, the film forming chamber 732 is a preliminary vapor-deposition chamber for forming a layer containing an organic compound or a metal material layer.

In the film forming chamber 712, a hole injecting layer formed from a high molecular weight material may be formed with an ink-jet method, a spin coating method, or the like. In addition, a film may be formed in reduced pressure by an ink-jet method with a substrate disposed longitudinally. Poly (ethylene dioxythiophene)/poly (styrenesulfonic acid) solution (PEDOT/PSS), polyaniline/camphor sulfonate solution (PANI/CSA), PTPDES, Et-PTPDEK, PPBA, or the like which operates as a hole injecting layer (an anode buffer layer) may be applied over the entire surface of the first electrode (anode) and be baked. It is preferable that the baking is performed in the baking chamber 723. When a hole injecting layer formed from a high molecular weight material is formed by a coating method using a spin coater or the like, planarity is improved, which can improve coverage and uniformity of a film thickness of a film formed thereover. Uniform light emitting can be obtained since a film thickness of the emission layer is especially uniform. In this case, it is preferable to perform heating (at temperatures from 100° C. to 200° C.) under reduced pressure just before forming a film by a vapor-deposition method after forming the hole injecting layer by a coating method. At the time of heating under reduced pressure, it may be performed in the pretreatment chamber 703b. For example, after washing the surface of the first electrode (anode) with a sponge, the substrate is carried in the cassette chamber 720a and 720b and is transferred to the film forming chamber 712, and poly (ethylene dioxythiophene)/poly (styrene sulfonic acid) solution (PEDOT/PSS) is entirely coated to have a film thickness of 60 nm with a spin coating method. Then, the substrate is transferred to the baking chamber 723, pre-baked at 80° C. for 10 minutes, and baked at 200° C. for an hour, and further heating under reduced pressure is performed (at 170° C., heating for 30 minutes, and cooling for 30 minutes) just before the vapor-deposition. Thereafter, the substrate is transferred to the film forming chambers 706R, 706G, and 706B and an emission layer is preferably formed by a vapor-deposition method without being exposed to an atmosphere. In particular, when an ITO film is used as an anode material and there is unevenness or a minor particle, it is possible to relieve the effect of such unevenness by having the PEDOT/PSS in a film thickness of 30 nm or more.

When the coating method is used, since the hole injecting layer formed from a high molecular weight material is formed over the entire surface of the substrate, it is preferable to remove a film containing an organic compound formed in an unnecessary place (edge surfaces and peripheral portions of the substrate, a terminal portion, a connection region of a cathode and lower wirings). In this case, it is preferable to transfer the substrate to the pretreatment chamber 703a and to remove the stacked layer of the organic compound film selectively. The pretreatment chamber 703a has a plasma generating means, and dry etching is performed by exciting one gas or a plurality of gases of Ar, H, F, and O to generate plasma. In addition, the pretreatment chamber 703a may be provided with an UV irradiation unit so that ultraviolet ray irradiation can be performed as anode surface treatment.

Then, the substrate is transferred to the film forming chamber 710 by the transfer unit provided in the transfer chamber 708 to form the second electrode to be a cathode. The cathode is an inorganic film (an alloy such as MgAg, MgIn, CaF₂, LiF, or CaN; a film formed of an element belonging to Group 1 or 2 and aluminum by a co-vapor-deposition method; or a stacked layer film thereof) formed by a vapor-deposition method using resistant heating.

In addition, in the case of manufacturing a top emission or dual emission light-emitting device, a cathode is preferably transparent or translucent, and a single layer of a transparent conductive film or a stacked layer of a thin film (1 nm to 10 nm thick) of the metal film and a transparent conductive film is preferably used for the cathode. In this case, a film formed of a transparent conductive film (ITO (indium tin oxide), indium zinc oxide (In₂O₃—ZnO), zinc oxide (ZnO), or the like) is preferably formed in the film forming chamber 709 by employing a sputtering method.

As mentioned above, light-emitting elements are manufactured. Each material of an anode, a layer containing an organic compound, and a cathode for forming the light-emitting elements is appropriately selected and each film thickness is adjusted, too. It is desirable to use the same materials for the anode and the cathode use and to have substantially the same film thickness, preferably a thin film of approximately 100 nm thick.

In addition, if necessary, a transparent protective layer for preventing penetration of moisture is formed by covering the light-emitting elements. A protective film formed of a silicon nitride film or a silicon nitride oxide film may be formed to perform sealing by transferring the substrate to the film forming chamber 713 connected to the transfer chamber 708. The film forming chamber 713 is provided therein with a target formed of silicon, a target formed of silicon oxide, or a target formed of silicon nitride. The transparent protective layer can be formed using a silicon nitride film, a silicon oxide film, or a silicon oxynitride film (an SiNO film (composition ratio of N>O) or an SiON film (composition ratio of N<O)); a thin film containing carbon as the main component (for example, a DLC film or a CN film); or the like that can be obtained by a sputtering method or a CVD method.

Hereinafter, a flow of performing the sealing step will briefly be described.

A first substrate where a layer containing an organic compound, a cathode, and the like are formed over an anode is introduced into the transfer chamber 714, and stored in the substrate stock chambers 730a and 730b or transferred to the delivery chamber 741. It is preferable that the transfer chamber 714, the substrate stock chambers 730a and 730b, and the delivery chamber 741 are kept under reduced pressure.

Then, the first substrate transferred to the delivery chamber 741 is transferred to the attaching chamber 744 by a transfer unit 748 installed in the transfer chamber 747.

A second substrate that serves as a sealing substrate is provided with columnar or wall-shaped structures, in advance. The second substrate is introduced into the sealing substrate loading chamber 717, and heated therein under reduced pressure so that degasification is performed. The second substrate is then transferred to the pretreatment chamber 746 provided with an UV irradiation unit by the transfer unit 748 that is installed in the transport chamber 747. In the pretreatment chamber, the surface of the second substrate is irradiated with ultraviolet light. The second substrate is next transferred to the chamber 745 for forming a sealing material to form a sealing material thereon. The chamber 745 for forming a sealing material is provided with a dispenser device or an ink-jet device. The chamber 745 for forming a sealing material may also be provided with a baking unit or an UV irradiation unit to pre-cure the sealing material. After pre-curing the sealing material in the chamber 145 for forming a sealing material, a filler is dropped in a region surrounded with the sealing material.

The second substrate is also transferred to the attaching chamber 744 by the transfer unit 748.

In the attaching chamber 744, after depressurizing the treatment chamber, the first and second substrates are attached to each other. At this moment, the first and second substrates are attached to each other by moving an upper plate or a lower plate up and down. Upon attaching the two substrates under reduced pressure, the gap between the substrates is kept precisely because of the columnar or wall-shaped structures that have been provided over the second substrate. The columnar or wall-shaped structures also importantly serve to disperse pressure applied to the substrates to prevent breakage of the substrates.

Alternatively, the filler may be dropped in the region surrounded with the sealing material in the attaching chamber 744, instead of the chamber 745 for forming a sealing material.

Instead of reducing the pressure within the entire treatment chamber, after making a space between the plates an airtight space by moving the upper and lower plates longitudinally, the airtight space therebetween may be depressurized by a vacuum pump connected to a hole that is provided in the lower plate. In such a way, since the volume to be depressurized is smaller as compared with the case of depressurizing the entire treatment chamber, the pressure within the airtight space can be reduced at short times.

Further, a transparent window may be provided in one of the upper and lower plates such that the sealing material may be cured by being irradiated with light that passes through the transparent window while maintaining the gap between the upper and lower plates and attaching the substrates to each other. In addition, dummy patterns of the sealing material are preferably provided outside of a pattern for the sealing material. After only the dummy patterns of the sealing material are cured with UV spot irradiation while maintaining the gap between the upper and lower plates and attaching the substrates to each other, the pressure within the treatment chamber that has been kept under reduced pressure is preferably increased up to atmospheric pressure. The entire pattern of the sealing material is then cured under atmospheric pressure. Even when the transparent window is provided in one of the upper and lower plates, a light shielding mask (a mask for protecting light-emitting elements from UV irradiation) or the like is formed in the substrates. Therefore, it is difficult to position the substrates such that the position of the pattern for the sealing material is adjusted to a position of light that passes through the transparent window. The positioning accuracy of the sealing material with respect to the light irradiation position is hardly ensured. Accordingly, it is more preferable that only the dummy patterns of the sealing material are cured by UV spot irradiation. Note that a plurality of holes is formed in one of the upper and lower plates such that the dummy patterns are cured with UV light transmitting through the plurality of holes.

The pair of substrates, witch is temporarily attached to each other, is transferred to the curing chamber 743 by the transfer unit 748. In the curing chamber 743, the sealing material is completely cured by light irradiation or heat treatment.

The pair of substrates is thus transferred to the unloading chamber 719 by the transfer unit 748. The pressure within the unloading chamber 719, which has been kept under reduced pressure, is increased up to atmospheric pressure, and then the pair of attached substrates is taken out therefrom. Consequently, the sealing step is completed while maintaining the constant gap between the substrates.

As mentioned above, by using the manufacturing apparatus of FIG. 7, substrates can be processed successively from the vapor-deposition step to the sealing step. However, since a higher reduced pressure is required in vapor-deposition as compared with that in the sealing step, upon transferring the substrates to a chamber for the sealing step from a chamber for vapor-deposition, the reduced pressure is necessary to be reduced before performing the sealing step. In the sealing step, the reduced pressure is set to be 1 Pa or less such that sudden vaporization of a solvent, which is contained in the sealing material, is prevented. In order to prevent adhesion of moisture or the like, an inert gas (nitrogen gas or the like) having a controlled dew point is preferably filled in the chambers (including the delivery chambers, the treatment chamber, the transfer chambers, the film forming chambers, and the like), other than the cassette chambers 720a and 720b; the transfer chamber 118; the film forming chamber 712; a baking chamber 723; the tray attachment stage 121; the unloading chamber 719; and the sealing substrate loading chamber 717. Desirably, pressure within such chambers is kept under reduced pressure.

This embodiment can be arbitrarily combined with the above embodiment modes.

### Embodiment 2

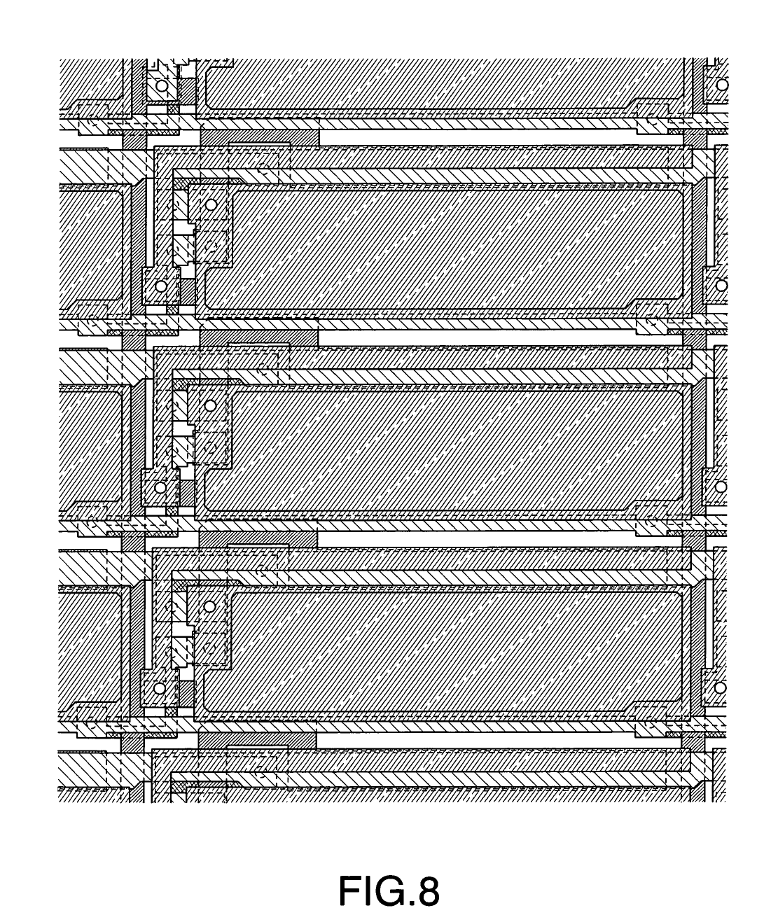

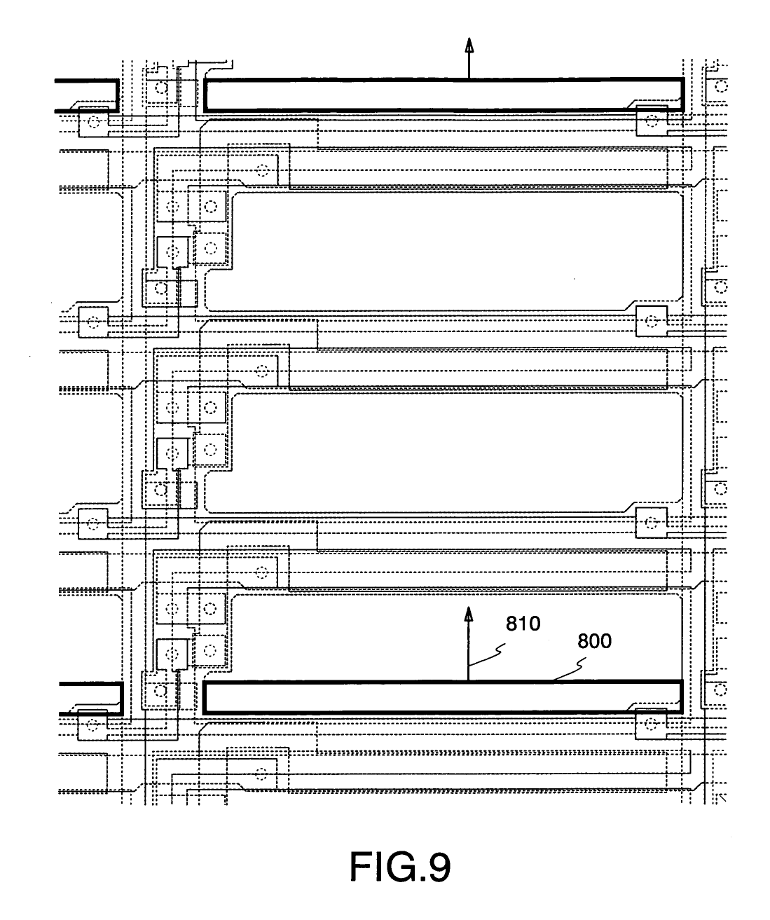

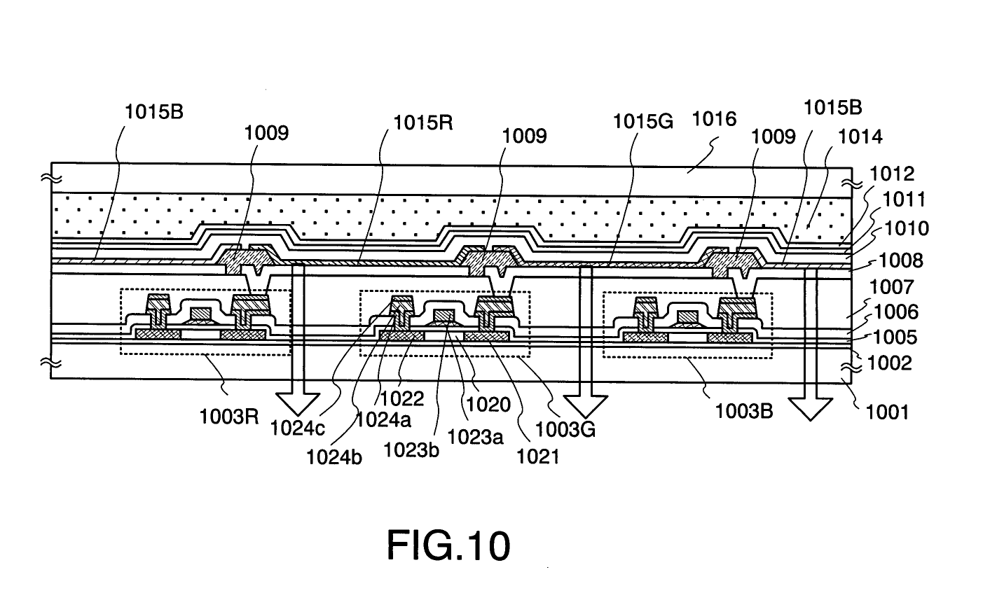

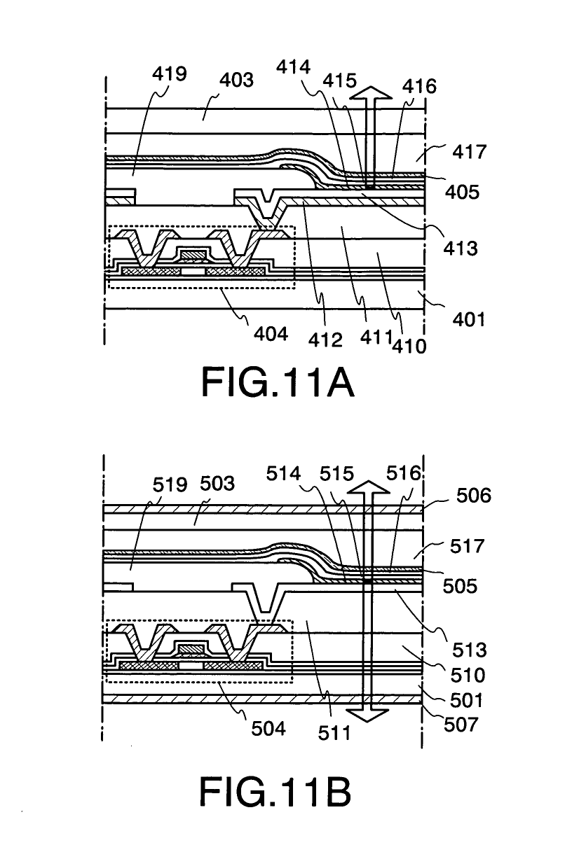

In this embodiment, a full-color light-emitting device obtained by using the vapor-deposition apparatus shown in FIG. 1 is described with reference to FIG. 8, FIG. 9, FIG. 10, and FIGS. 11A and 11B.

FIG. 8 is a top view showing an example of a layout of a pixel in an active matrix light-emitting device. In addition, FIG. 9 is a view showing relation between a layout of a pixel and an opening 800 of a mask, which is a top view corresponding to FIG. 8. At the time of vapor-deposition, vapor-deposition of a pixel for emitting a luminescent color is performed by moving a vapor-deposition mask in the direction of an arrow 810 shown in FIG. 9.

In addition, FIG. 10 is a view partially showing a cross section of the active matrix light-emitting device.

Three TFTs 1003R, 1003G, and 1003B are provided over a base film 1002 over a first substrate 1001. These TFTs are p-channel TFTs each having a channel forming region 1020 and source/drain regions 1021 and 1022, which each serve as an active layer, a gate insulating film 1005, and gate electrodes 1023a and 1023b. In addition, the gate electrode is formed of two layers having the lower layer 1023a to be tapered and the upper layer 1023b.

In addition, a high thermostability planarizing film 1007 is a planarized interlayer insulating film formed by a coating method. The planarized interlayer insulating film formed by a coating method refers to an interlayer insulating film formed by coating a liquid composition. The materials such as an organic resin such as acrylic or polyimide; a so-called coating silicon oxide film (Spin on Glass and hereinafter also referred to as “SOG”) which is coated by heat treatment after a material for an insulating film dissolved in an organic solvent is coated; or a material for forming a siloxane bond by baking siloxane polymer or the like can be given as an example of the planarized interlayer insulating film formed by a coating method. Not limiting to a coating method, the high thermostability planarizing film 1007 can be formed also using an inorganic insulating film such as a silicon oxide film formed by a vapor phase growth method or a sputtering method. Further, a planarizing insulating film formed by a coating method may be stacked after forming a silicon nitride film as a protective film by a PCVD method or a sputtering method.

In light-emitting elements, it is important that a first electrode 1008 is planarized. When the high thermostability planarizing film 1007 is not planarized, there is a fear that the first electrode 1008 is not planarized too due to the surface unevenness of the high thermostability planarizing film 1007. Therefore, the planarity of the high thermostability planarizing film 1007 is important.

In addition, drain/source wirings 1024a, 1024b, and 1024c are formed in three layers. Here, a stacked-layer film of a Ti film, an Al (C+Ni) alloy film, and a Ti film is used. The drain/source wirings 1024a to 1024c of the TFTs 1003R, 1003G and 1003B are each preferably formed in a tapered shape in consideration of the coverage of the interlayer insulating film.

Moreover, a bank 1009 is resin, which serves as a partition between layers containing organic compounds 1015B, 1015R and 1015G each emitting different luminescence. Therefore, the bank 1009 is formed in a lattice shape so that one pixel, in other words, a light-emitting region is surrounded. The layer containing organic compounds 1015B, 1015R and 1015G emitting different luminescence may be overlapped over the bank but not overlapped with the first electrode 1008 in neighboring pixels.

A red light-emitting element is formed of a first electrode 1008 formed from a transparent conductive material, a layer containing an organic compound 1015R, and a second electrode 1010. A green light-emitting element is formed of a first electrode 1008 formed from a transparent conductive material, a layer containing an organic compound 1015G, and the second electrode 1010. In addition, a blue light-emitting element is formed of a first electrode 1008 formed from a transparent conductive material, a layer containing an organic compound 1015B, and the second electrode 1010.

Further, the materials for the first electrode 1008 and the second electrode 1010 have to be selected in consideration of a work function. However, either the first electrode 1008 or the second electrode 1010 can be an anode or a cathode depending on a pixel structure. When a polarity of the driving TFT is a p-channel type, it is preferable that the first electrode 1008 serves as an anode and the second electrode 1010 serves as a cathode. When a polarity of the driving TFT is an n-channel type, it is preferable that the first electrode 1008 serves as a cathode and the second electrode 1010 serves as an anode.

An HIL (hole injecting layer), an HTL (hole transporting layer), an EML (emission layer), an ETL (electron transporting layer), and an EIL (electron injecting layer) are sequentially laminated on the first electrode 1008 (anode) side in the layers containing an organic compound 1015R, 1015G, and 1015B. A single layer structure or a mixed structure other than the stacked structure can be employed for the layers containing an organic compound 1015B, 1015R and 1015G In order to obtain the full-color light-emitting device, the layers containing an organic compound 1015R, 1015G, and 1015B each are selectively formed to form three kinds pixels of R, G, and B.

Furthermore, in order to protect the light-emitting elements from damage due to moisture or degassing, it is preferable to provide protective films 1011 and 1012 covering the second electrode 1010. The protective films 1011 and 1012 are preferably formed using a dense inorganic insulating film (an SiN film, an SiNO film, and the like) formed by a PCVD method, a dense inorganic insulating film (an SiN film, an SiNO film, and the like) formed by a sputtering method, a thin film containing carbon as the main component (a DLC film, a CN film, and an amorphous carbon film), a metal oxide film (WO₂, Al₂O₃, and the like), CaF₂, or the like.

A filler material 1014 is filled between the first substrate 1001 and a second substrate 1016.

In addition, light of the light-emitting elements is extracted through the substrate 1001. The structure shown in FIG. 10 is a bottom emission light-emitting device.

Although a top gate TFT is exemplified here, the present invention can be applied despite a TFT structure and, for example, a bottom gate (reverse stagger) TFT or a forward stagger TFT can be applied.

This embodiment can be arbitrarily combined with Embodiment Mode 1, Embodiment Mode 2, or Embodiment 1.

### Embodiment 3

Whereas an example of a bottom emission light-emitting device is described in Embodiment 2, an example of manufacturing a top emission light-emitting device is described in this embodiment with refering to FIG. 11A.

First, a base insulating film is formed over a first substrate 401. The first substrate 401 is not limited particularly as long as it has planarity and heat resistance. A base film formed of an insulating film such as a silicon oxide film, a silicon nitride film, or a silicon oxynitride film is formed as the base insulating film.

Secondly, a semiconductor layer is formed over the base insulating film. A semiconductor film having an amorphous structure is formed with a known means (a sputtering method, an LPCVD method, a plasma CVD method, or the like). Thereafter, a crystalline semiconductor film obtained by performing known crystallization processing (a laser crystallization method, a thermal crystallization method, a thermal crystallization method using a catalyst such as nickel, or the like) is formed in a desired shape by patterning with a first photomask. The semiconductor layer is formed in a thickness of from 25 nm to 80 nm (preferably, from 30 nm to 70 nm). Although a material of the crystalline semiconductor film is not limited, the semiconductor film is preferably formed from silicon, a silicon germanium (SiGe) alloy, or the like.

In addition, the crystallization processing for the semiconductor film having an amorphous structure may be performed using a continuous-wave laser, and in crystallizing the amorphous semiconductor film, it is preferable to employ the second harmonic to the fourth harmonic of a fundamental by using a solid laser capable of continuous oscillation in order to obtain a crystal having a large grain size. Typically, the second harmonic (532 nm) or the third harmonic (355 nm) of a Nd: YVO₄ laser (fundamental 1064 nm) is preferably employed.

After removing the resist mask, a gate insulating film covering the semiconductor layer is formed. The gate insulating film is formed in a thickness from 1 nm to 200 nm by using a plasma CVD method, a sputtering method, or a thermal oxidation method.

A conductive film in a thickness of 100 nm to 600 nm is formed over the gate insulating film thereafter. Here, a conductive film formed of a stacked layer of a TaN film and a W film is formed using a sputtering method. Although the conductive film here is the stacked layer of a TaN film and a W film, the conductive film is not limited particularly. The conductive film may be formed from an element of Ta, W, Ti, Mo, Al, and Cu; a single layer of an alloy material or a compound material containing the element as the main component; or a stacked layer thereof. Alternatively, a semiconductor film typified by a polycrystalline silicon film in which an impurity element-such as phosphor is doped may also be used.

Then, a resist mask is formed using a second photomask to perform etching by using a dry etching method or a wet etching method. A gate electrode of a TFT 404 is formed by etching the conductive film according to the etching step.

After removing the resist mask, a resist mask is newly formed using a third photomask, and in order to form an n-channel TFT which is not shown in the figure, a first doping step for doping an impurity element imparting n-type conductivity (typically, P (phosphor) or As (arsenic)) to a semiconductor to form a low-concentration region is performed. The resist mask covers a region to be a p-channel TFT and the vicinity of the conductive layer. According to the first doping step, through doping is performed by interposing the insulating film to form an n-type low-concentration impurity region. Although one light-emitting element is driven using a plurality of TFTs, the doping step is not particularly necessary when the light-emitting element is driven using only p-channel TFTs.

After removing the resist mask, a resist mask is newly formed using a fourth photomask, and a second doping step for doping an impurity element imparting p-type conductivity (typically, B (boron)) to a semiconductor to form a high-concentration region is performed. According to the second doping step, through doping is performed by interposing the gate insulating film to form a p-type high-concentration impurity region.

Then, a resist mask is newly formed using a fifth photomask, and in order to form an n-channel TFT which is not shown in the figure, a third doping step for doping an impurity element imparting n-type conductivity (typically, P (phosphor) or As (arsenic)) to a semiconductor to form a high-concentration region is performed. The resist mask covers a region to be a p-channel TFT and the vicinity of the conductive layer. According to the third doping step, through doping is performed by interposing the insulating film to form an n-type high-concentration impurity region.

Thereafter, after forming an insulating film containing hydrogen by removing the resist mask, the impurity element added into the semiconductor layer is activated and hydrogenated. The insulating film containing hydrogen is formed using a silicon nitride oxide film (SiNO film) obtained by a PCVD method.

Then, a planarizing film 410 to be a second-layer interlayer insulating film is formed. The planarizing film 410 is formed using an inorganic material (silicon oxide, silicon nitride, silicon oxynitride, or the like); a photosensitive or non-photosensitive organic material (polyimide, acrylic, polyamide, polyimide amide, resist, or benzocyclobutene); a stacked layer thereof; or the like. In addition, an insulating film formed of a SiOₓ film containing an alkyl group that is obtained by a coating method, for example, an insulating film formed using silica glass, an alkyl siloxane polymer, an alkyl silsesquioxane polymer, a hydrogenated silsesquioxane polymer, a hydrogenated alkyl silsesquioxane polymer, or the like can be used as another film used for the planarizing film. There are coating materials for an insulating film such as #PSB-K1 and #PSB-K31 manufactured by Toray Industries, Inc. and #ZRS-5PH manufactured by Catalysts & Chemicals Industries Co., Ltd. as an example of a siloxane-based polymer.

Next, a contact hole is formed in the interlayer insulating film by using a sixth mask. After removing the sixth mask to form a conductive film (a TiN film, an Al (C+Ni) alloy film, and a TiN film), etching is performed using a seventh mask to form a wiring (source/drain wirings, a current supply wiring, and the like of a TFT).

A third-layer interlayer insulating film 411 is formed by removing the seventh mask thereafter. The third-layer interlayer insulating film 411 is formed using a photosensitive or non-photosensitive organic material in which black colorant is dispersed that is obtained by a coating method. In this embodiment, a light-shielding interlayer insulating film is used to improve contrast and to absorb straight light. In order to protect the third-layer interlayer insulating film 411, a silicon nitride oxide film (SiNO film) obtained by a PCVD method may be stacked as a fourth-layer interlayer insulating film. When the fourth-layer interlayer insulating film is formed, it is preferable that the fourth-layer interlayer insulating film is selectively removed by using a first electrode as a mask after patterning the first electrode in the following step.

Then, a contact hole is formed in the third-layer interlayer insulating film 411 by using an eighth mask.

After forming a reflective conductive film and a transparent conductive film, patterning is performed using a ninth mask to obtain a stacked layer of a reflective electrode 412 and a transparent electrode 413. The reflective electrode 412 is formed using Ag, Al, or an Al (C+Ni) alloy film. Besides indium tin oxide (ITO), for example, the transparent electrode 413 can be formed using a transparent conductive material such as indium tin oxide containing a Si element (ITSO) or IZO (Indium Zinc Oxide) in which 2% to 20% of zinc oxide (ZnO) is mixed in indium oxide.

Next, an insulator 419 to be a bank by covering an edge of the reflective electrode 412 and the transparent electrode 413 is formed by using a tenth mask. The insulator 419 is formed using a photosensitive or non-photosensitive organic material (polyimide, acrylic, polyamide, polyimide amide, resist, or benzocyclobutene) or a SOG film (for example, a SiOₓ film including an alkyl group) in the range of a film thickness from 0.8 μm to 1 μm.

A layer containing an organic compound 414 is formed using a vapor-deposition method or a coating method thereafter. In order to obtain a full-color light-emitting element, the layers containing an organic compound 414 are each selectively formed to form three kinds of pixels of R, G, and B.

Then, a transparent electrode 415, in other words, a cathode of organic light-emitting elements is formed over the layer containing an organic compound 414 ranging from 10 nm thick to 800 nm thick. Besides indium tin oxide (ITO), for example, the transparent electrode 415 can be formed using indium tin oxide containing a Si element (ITSO) or IZO (Indium Zinc Oxide) in which 2% to 20% of zinc oxide (ZnO) is mixed in indium oxide.

The light-emitting elements are formed in the foregoing manner.

Next, transparent protective layers 405 and 416 for preventing penetration of moisture are formed to cover the light-emitting elements. The transparent protective layers 405 and 416 can be formed using a silicon nitride film, a silicon oxide film, a silicon oxynitride film (a SiNO film (composition ratio N>O) or a SiON film (composition ratio N<O)), a thin film containing carbon as the main component (for example, a DLC film or a CN film), or the like that can be obtained by a sputtering method or a CVD method.

Then, a second substrate 403 and the first substrate 401 are attached to each other using a sealing material containing a gap material (a filler (a fiber rod), fine particles (a silica spacer), and the like) for maintaining a gap between the substrates. A filler material 417, typically, an ultraviolet curable-epoxy resin or a thermosetting-epoxy resin is filled between a pair of the substrates. In addition, a glass substrate, a quartz substrate, or a plastic substrate each having a light-transmitting property are preferably used for the second substrate 403. As compared with the case where there is a space (inert gas) between the pair of the substrates, the entire transmissivity can be improved by filling a transparent filler material (reflective index of approximately 1.50) between the pair of the substrates.

As shown in FIG. 11A, the transparent electrode 415, the transparent protective layers 416 and 405, and the filler material 417 of the light-emitting elements according to this embodiment are formed from light-transmitting materials so that each of the light-transmitting elements can emit light upward as denoted by an outline arrow.

Hereinafter, an example of manufacturing a dual emission light-emitting device is described with reference to FIG. 11B.

First, a base insulating film is formed over a first light-transmitting substrate 501. The first substrate 501 is not limited particularly as long as it is a light-transmitting substrate.

Secondly, a semiconductor layer is formed over the base insulating film. Then, a gate insulating film for covering the semiconductor layer is formed and a gate electrode is formed over the gate insulating film.

Then, an n-type low-concentration impurity region, a p-type high-concentration impurity region, an n-type high-concentration impurity region, or the like are formed appropriately by performing doping. After forming an insulating film (a light-transmitting interlayer insulating film) containing hydrogen by removing a resist mask, an impurity element added into the semiconductor layer are activated and hydrogenated.

A light-transmitting planarizing film 501 to be a second-layer interlayer insulating film is formed thereafter. The light-transmitting planarizing film 501 is formed using an organic material (silicon oxide, silicon nitride, silicon oxynitride, or the like); a photosensitive or non-photosensitive organic material (polyimide, acrylic, polyamide, polyimide amide, resist, or benzocyclobutene); a stacked layer thereof; or the like.

After forming a contact hole in the interlayer insulating film, a conductive film (a TiN film, an Al (C+Ni) alloy film, and a TiN film) is formed, ant then, etching is selectively performed to form a wiring (source/drain wirings, a current supply wiring, and the like of a TFT), therefore, TFT 504 is formed.

Then, a third-layer interlayer insulating film 511 is formed. The third-layer interlayer insulating film 511 is formed using an insulating film formed of a SiOₓ film containing an alkyl group that is obtained by a coating method. In order to protect the third-layer interlayer insulating film 511, a silicon nitride oxide film (SiNO film) obtained by a PCVD method may be stacked as a fourth-layer interlayer insulating film. When the fourth-layer interlayer insulating film is formed, it is preferable that the fourth-layer interlayer insulating film is selectively removed by using a first electrode as a mask after patterning the first electrode in the following step.

A contact hole is formed in the third-layer interlayer insulating film 511 thereafter.

After forming a transparent conductive film, a transparent electrode 513 is obtained by performing patterning. Besides indium tin oxide (ITO), for example, the transparent electrode 513 is formed using a transparent conductive material having a high work function such as indium tin oxide containing a Si element (ITSO) or IZO (Indium Zinc Oxide) in which 2% to 20% of zinc oxide (ZnO) is mixed in indium oxide.

Then, an insulator 519 for covering an edge of the transparent electrode 513 is formed by using a mask.

A layer containing an organic compound 514 is formed using a vapor-deposition method or a coating method thereafter.

Then, a transparent electrode 515, in other words, a cathode of organic light-emitting elements is formed over the layer containing an organic compound 514 ranging from 10 nm thick to 800 nm thick. Besides indium tin oxide (ITO), for example, the transparent electrode 515 can be formed using indium tin oxide containing a Si element (ITSO) or IZO (Indium Zinc Oxide) in which 2% to 20% of zinc oxide (ZnO) is mixed in indium oxide.

Next, transparent protective layers 505 and 516 for preventing penetration of moisture are formed to cover the light-emitting elements. Thereafter, a second substrate 503 and the substrate 501 are attached to each other using a sealing material containing a gap material for maintaining a gap between the substrates. In addition, a glass substrate, a quartz substrate, or a plastic substrate each having a light-transmitting property are preferably used for the second substrate 503.

As shown in FIG. 11B, the transparent electrode 515 and a filler material 517 of the light-emitting elements thus obtained are formed from light-transmitting materials so that each of the light-transmitting elements can emit light upward and downward as denoted by an outline arrow.

Last, optical films (a polarizing plate or a circularly polarizing plate) 506 and 507 are provided to improve a contrast.

For example, the substrate 501 is provided with an optical film (a λ/4 plate and a polarizing plate are sequentially disposed over the substrate) 507 and the second substrate 503 is provided with an optical film (a λ/4 plate and a polarizing plate are sequentially disposed over the substrate) 506.

In addition, as another example, the substrate 501 is provided with an optical film (a λ/4 plate, a λ/2 plate, and a polarizing plate are sequentially disposed over the substrate) 507 and the second substrate 503 is provided with an optical film (a λ/4 plate, a λ/2 plate, and a polarizing plate are sequentially disposed over the substrate) 506.

Thus, according to the invention, a polarizing plate, a circularly polarizing plate, or a combination thereof can be provided according to a structure of a dual emission light-emitting device. Therefore, a clear black display can be performed and a contrast is improved. Further, a circularly polarizing plate can prevent reflective light.

This embodiment can be arbitrarily combined with Embodiment Mode 1, Embodiment Mode 2, Embodiment 1, or Embodiment 2.

### Embodiment 4

An example of mounting an FPC or a driver IC on an EL display panel manufactured according to the foregoing embodiments is described in this embodiment.

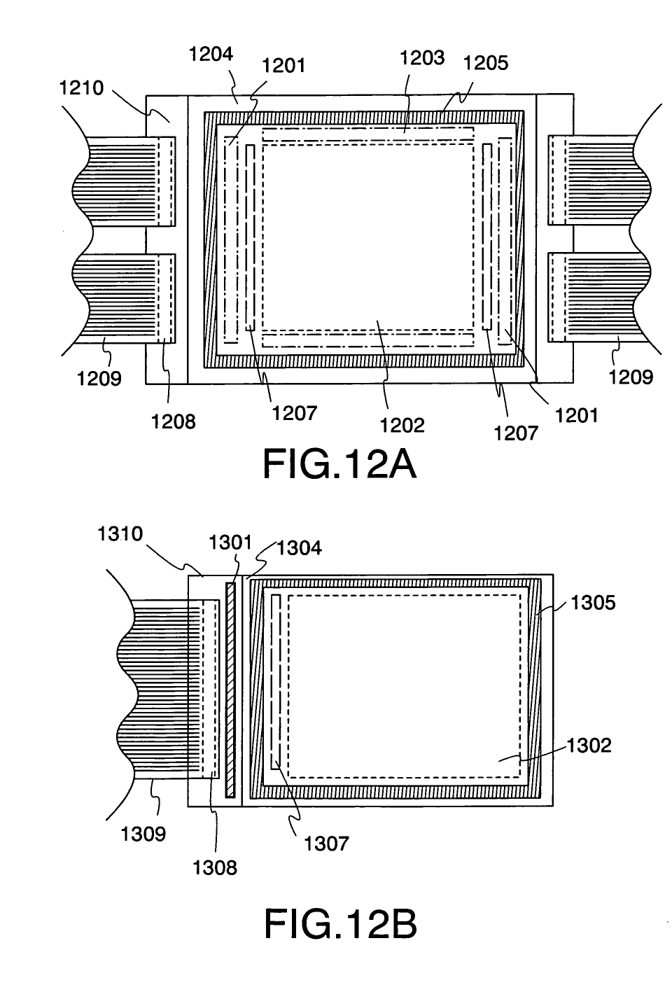

FIG. 12A is an example showing a top view of a light-emitting device in which each FPC 1209 is attached to four terminal portions 1208. A pixel portion 1202 including a light-emitting element and a TFT, a gate-side driver circuit 1203 including a TFT, and a source-side driver circuit 1201 including a TFT are formed over a substrate 1210. These circuits can be formed over one substrate when an active layer of a TFT is constructed from a semiconductor film having a crystalline structure. Therefore, an EL display panel in which the system-on-panel is realized can be manufactured.

Note that a portion of the substrate 1210 except a contact portion is covered with a protective film and a base layer containing a photocatalytic material is provided over the protective film.

Two connecting regions 1207 provided so as to sandwich the pixel portion are provided for contacting a second electrode of a light-emitting element to a lower wiring. Note that the first electrode of a light-emitting element is electrically connected to the TFT provided for the pixel portion.

A sealing substrate 1204 is fixed to the substrate 1210 by a sealing member 1205 surrounding the pixel portion and the driving circuits and by a filler surrounded with the sealing member. In addition, a structure in which a filler including a transparent desiccate is filled may also be employed. The desiccate may be disposed in a region which is not overlapped with the pixel portion.

A structure shown in FIG. 12A is suitable for a light-emitting device of a relatively large size of XGA class (for example, the opposite angle: 4.3 inches). In FIG. 12B, a COG mode which is suitable for a light-emitting device of a small size (for example, the opposite angle: 1.5 inches) is employed.

In FIG. 12B, a driver IC 1301 is mounted on a substrate 1310 and an FPC 1309 is mounted on a terminal portion 1308 disposed at the end of the driver IC. A plurality of the driver ICs 1301 to be mounted are preferably formed over a rectangular substrate to be 300 mm to 1000 mm or more in one side, from a view point of improving the productivity. In other words, a plurality of circuit patterns having a driver circuit portion and an input/output terminal as a unit is preferably formed over a substrate to take out last by being divided. The driver IC may be formed to be rectangular in a longer side of 15 nm to 80 mm and in a shorter side of 1 nm to 6 mm, or may be formed to have a length of a longer side which is a length of one side of a pixel region or a length adding one side of a pixel portion to one side of each driving circuit.

The driver IC is favorable in external dimensions because a longer side can be made in an IC chip. When a driver IC formed to be 15 nm to 80 mm in a longer side is used, the number of driver ICs to be required for being mounted to a pixel portion is reduced, compared with the case of using an IC chip, thereby improving the yield in manufacturing. When a driver IC is formed over a glass substrate, the productivity is not deteriorated because there is no limitation in the shape of a substrate used as a parental body. This is a great advantage compared with the case of taking out an IC chip from a circular silicon wafer.

In addition, a TAB mode may be employed, and in that case, a plurality of tapes is attached and a driver IC may be mounted on the tapes. As in the case of the COG mode, a single driver IC may be mounted on a single tape. In this case, a metal piece or the like for fixing a driver IC is preferably attached jointly for the intensity.

The substrate except a contact portion is covered with a protective film and a base layer containing a photocatalytic material is provided over the protective film.

A connecting region 1307 provided between a pixel portion 1302 and the driving IC 1301 is provided for contacting a second electrode of a light-emitting element to a lower wiring. Note that the first electrode of a light-emitting element is electrically connected to the TFT provided for the pixel portion.

A sealing substrate 1304 is fixed to the substrate 1310 by a sealing member 1305 surrounding the pixel portion 1302 and by a filler surrounded with the sealing member.

In the case of using an amorphous semiconductor film as an active layer of a TFT, since it is difficult to form a driver circuit over one substrate, the structure shown in FIG. 12B is employed even in a large size.

This embodiment can be arbitrarily combined with Embodiment Mode 1, Embodiment Mode 2, Embodiment 1, Embodiment 2, or Embodiment 3.

### Embodiment 5

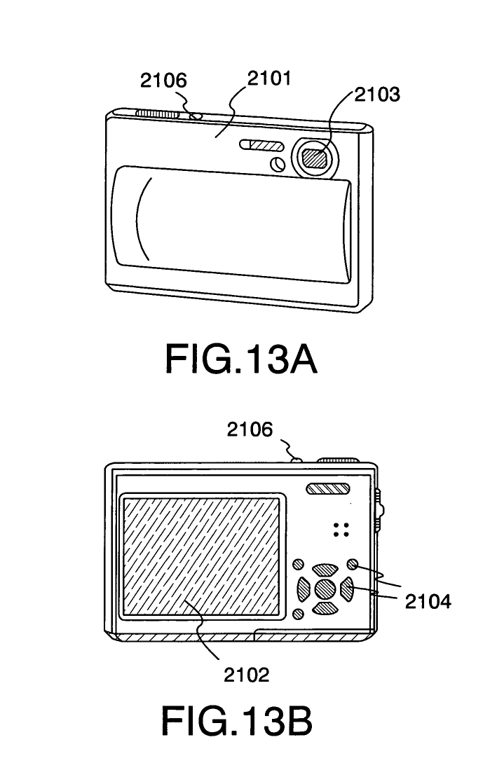

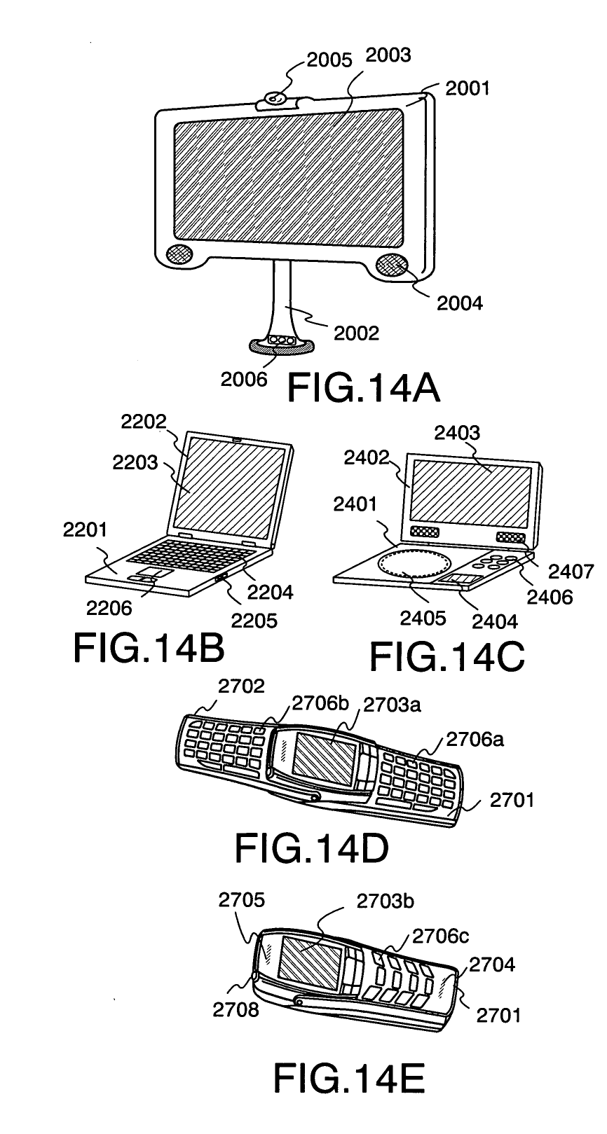

The following can be given as an example of a display device and an electronic device according to the present invention: a camera such as a video camera or a digital camera, a goggle type display (head mounted display), a navigation system, an audio reproducing device (a car audio, an audio component, and the like), a personal computer, a game machine, a portable information terminal (a mobile computer, a cellular phone, a portable game machine, an electronic book, and the like), an image reproduction device provided with a recording medium (specifically a device that is capable of playing a recording medium such as a Digital Versatile Disc (DVD) and that has a display device that can display the image), and the like. FIGS. 13A and 13B and FIGS. 14A to 14E each show a specific example of the electronic devices.

FIGS. 13A and 13B each show a digital camera, which includes a main body 2101, a display portion 2102, an imaging portion 2103, operation keys 2104, a shutter 2106, and the like. According to the invention, a digital camera having a full-color display portion 2102 capable of a well-contrast display can be realized.

FIG. 14A shows a large-sized display device having a large screen of 22 inches to 50 inches, which includes a casing 2001, a support 2002, a display portion 2003, a speaker portion 2004, an imaging portion 2005, a video input terminal 2006, and the like. Note that the display device includes every display device for an information display, for example, for a personal computer, for TV broadcast reception, and the like. According to the invention, a large-sized full-color display device capable of a well-contrast display can be completed even in the case of the large screen of 22 inches to 50 inches.

FIG. 14B shows a laptop computer, which includes a main body 2201, a casing 2202, a display portion 2203, a keyboard 2204, an external-connection port 2205, a pointing mouse 2206, and the like. According to the invention, a full-color laptop computer capable of well-contrast display can be completed.

FIG. 14C shows a mobile image reproduction device with a recording medium (specifically, a DVD reproducing device), which includes a main body 2401, a casing 2402, a display portion A 2403, a display portion B 2404, a recording medium (DVD and the like) reading portion 2405, operation keys 2406, a speaker portion 2407, and the like. The display portion A 2403 mainly displays image information, and the display portion B 2404 mainly displays character information. Note that the video reproduction device includes a home-use game machine and the like. According to the invention, a full-color image reproduction device capable of well-contrast display can be completed.

FIG. 14D is a perspective view of a personal digital assistance, and FIG. 14E is a perspective view showing a state of using it as a folding cellular phone. In FIG. 14D, users operate operation keys 2706a with their right fingers and operate operation keys 2706b with their left fingers, as a keyboard. According to the invention, a full-colored personal digital assistance capable of well-contrast display can be completed.

As shown in FIG. 14E, in folding a cellular phone, users have a main body 2701 and a casing 2702 in one hand and use an audio input portion 2704, an audio output portion 2705, operation keys 2706c, an antenna 2708, and the like.

The personal digital assistance shown in FIGS. 14D and 14E each includes a high-definition display portion 2703a which horizontally displays images and characters mainly and a display portion 2703b which vertically displays.

As described above, several electronic devices can be completed by employing a manufacturing method or a structure of any one of Embodiment Mode 1, Embodiment Mode 2, Embodiment 1, Embodiment 2, Embodiment 3, or Embodiment 4.

The present application is based on Japanese Patent Application serial No. 2004-208955 filed on Jul. 15, 2004 with the Japanese Patent Office, the entire contents of which are hereby incorporated by reference.

What is claimed is:

1. A manufacturing apparatus comprising:
a load chamber;
a transfer chamber connected to the load chamber; and
a film formation chamber connected to the transfer chamber,
wherein the film formation chamber is connected to a pressure reducing chamber that reduces pressure of the film formation chamber,
wherein the film formation chamber includes
means for moving a substrate for moving and fixing a substrate,
means for moving a mask in the film formation chamber,
an imaging means for aligning the mask and the substrate,
a vapor deposition source below the substrate and the mask, and
a movement unit for moving the vapor deposition source.

2. The manufacturing apparatus according to claim 1, wherein the mask has a thickness of 10 μm to 100 μm.

3. The manufacturing apparatus according to claim 1, wherein the mask is moved relatively with respect to the substrate simultaneously with performing film formation to the substrate in the film formation chamber.

4. The manufacturing apparatus according to claim 1, wherein a film is formed by repeating film formation more than once after moving the mask respectively with respect to the substrate in the film formation chamber.

5. The manufacturing apparatus according to claim 1, wherein the substrate is provided with a plurality of electrodes arranged regularly and an insulator between neighboring electrodes for covering electrode ends, wherein one side of an opening provided for the mask is equal to one side of the electrode and an area of the opening is smaller than that of the electrode.

6. The manufacturing apparatus according to claim 1, wherein a shape of the opening provided for the mask is a rectangle or a rhomboid.

7. A manufacturing apparatus comprising:
a load chamber;
a transfer chamber connected to the load chamber; and
a film formation chamber connected to the transfer chamber,
wherein the film formation chamber is connected to a pressure reducing chamber that reduces pressure of the film formation chamber,
wherein the film formation chamber includes
a means for moving a mask for moving and fixing a mask,
a means for moving a substrate in the film formation chamber,
an imaging means for aligning the mask and the substrate,
a vapor deposition source below the substrate and the mask, and
a movement unit for moving the vapor deposition source.

8. The manufacturing apparatus according to claim 7, wherein the mask has a thickness of 10 μm to 100 μm.

9. The manufacturing apparatus according to claim 7, wherein the mask is moved relatively with respect to the substrate simultaneously with performing film formation to the substrate in the film formation chamber.

10. The manufacturing apparatus according to claim 7, wherein a film is formed by repeating film formation more than once after moving the mask respectively with respect to the substrate in the film formation chamber.

11. The manufacturing apparatus according to claim 7, wherein the substrate is provided with a plurality of electrodes arranged regularly and an insulator between neighboring electrodes for covering electrode ends, wherein one side of an opening provided for the mask is equal to one side of the electrode and an area of the opening is smaller than that of the electrode.

12. The manufacturing apparatus according to claim 7, wherein a shape of the opening provided for the mask is a rectangle or a rhomboid.

13. A manufacturing apparatus comprising:
a load chamber;
a transfer chamber connected to the load chamber; and
a film formation chamber connected to the transfer chamber,
wherein the film formation chamber is connected to a pressure reducing chamber that reduces pressure of the film formation chamber,
wherein the film formation chamber includes
a means for moving a substrate for moving fixing a substrate,
a means for moving a mask in the film formation chamber,
an imaging means for aligning the mask and the substrate, and
a fixed vaporize means.

14. The manufacturing apparatus according to claim 13, wherein the mask has a thickness of 10 μm to 100 μm.

15. The manufacturing apparatus according to claim 13, wherein the mask is moved relatively with respect to the substrate simultaneously with performing film formation to the substrate in the film formation chamber.

16. The manufacturing apparatus according to claim 13, wherein a film is formed by repeating film formation more than once after moving the mask respectively with respect to the substrate in the film formation chamber.

17. The manufacturing apparatus according to claim 13, wherein the substrate is provided with a plurality of electrodes arranged regularly and an insulator between neighboring electrodes for covering electrode ends, wherein one side of an opening provided for the mask is equal to one side of the electrode and an area of the opening is smaller than that of the electrode.

18. The manufacturing apparatus according to claim 13, wherein a shape of the opening provided for the mask is a rectangle or a rhomboid.

19. A manufacturing apparatus comprising:
a load chamber;
a transfer chamber connected to the load chamber; and
a film formation chamber connected to the transfer chamber,
wherein the film formation chamber is connected to a pressure reducing chamber that reduces pressure of the film formation chamber,
wherein the film formation chamber includes
a means for moving a mask for fixing a mask,
a means for moving a substrate in an X direction and a Y direction with respect to the mask in the film formation chamber,
an imaging means for aligning the mask and the substrate, and
a fixed vaporize means.

20. The manufacturing apparatus according to claim 19, wherein the mask has a thickness of 10 μm to 100 μm.

21. The manufacturing apparatus according to claim 19, wherein the mask is moved relatively with respect to the substrate simultaneously with performing film formation to the substrate in the film formation chamber.

22. The manufacturing apparatus according to claim 19, wherein a film is formed by repeating film formation more than once after moving the mask respectively with respect to the substrate in the film formation chamber.

23. The manufacturing apparatus according to claim 19, wherein the substrate is provided with a plurality of electrodes arranged regularly and an insulator between neighboring electrodes for covering electrode ends, wherein one side of an opening provided for the mask is equal to one side of the electrode and an area of the opening is smaller than that of the electrode.

24. The manufacturing apparatus according to claim 19, wherein a shape of the opening provided for the mask is a rectangle or a rhomboid.
